(19) United States
(12) Patent Application Publication
(10) Pub. No.: US 2009/0057767 A1
(43) Pub. Date: Mar. 5, 2009

(54) SEMICONDUCTOR DEVICE, METHOD FOR MANUFACTURING THE SAME, AND METHOD FOR DRIVING THE SAME

(76) Inventors: Nobuyoshi Takahashi, Toyama (JP); Keita Takahashi, Nara (JP)

Correspondence Address: MCDERMOTT WILL & EMERY LLP, 600 13TH STREET, NW, WASHINGTON, DC, 20005-3096, US

(21) Appl. No.: 12/197,541

(22) Filed: Aug. 25, 2008

(30) Foreign Application Priority Data
Aug. 29, 2007 (JP) 2007-222139

(51) Int. Cl. H01L 27/092; H01L 21/8238; H03K 3/353

(52) U.S. Cl. 257/357; 438/232; 327/109; 257/E27.062; 257/E21.632

(57) ABSTRACT

A semiconductor device includes a protected device formed on a semiconductor substrate, a first protection transistor formed in a second well of a second conductivity type, and a second protection transistor formed in a first well of a first conductivity type. A fourth source/drain diffusion layer of the second protection transistor is in contact with a second diffusion layer, and a third source/drain diffusion layer is in contact with a second source/drain diffusion layer of the first protection transistor in the second well. A first source/drain diffusion layer of the first protection transistor is in contact with a first diffusion layer, which is in contact with a protected device electrode.

### CROSS REFERENCE TO RELATED APPLICATION

This application claims priority under 35 U.S.C. §119 on Patent Application No. 2007-222139 filed in Japan on Aug. 29, 2007, the entire contents of which are hereby incorporated by reference.

### BACKGROUND OF THE INVENTION

1. Field of the Invention

The present invention relates to a semiconductor device, a method for manufacturing the same and a method for driving the same, and more particularly to a semiconductor device including a local charge trapping type non-volatile memory, or the like, and a method for manufacturing the same, and a method for driving the same.

2. Description of the Background Art

Once a charge is injected into a local charge trapping type non-volatile memory due to the charge-up during the diffusion step, it is often difficult to remove the injected charge after the manufacturing process is completed. It has therefore become important to develop a technique of suppressing the charge-up damage to a memory portion during the diffusion step. Techniques have been researched in the art for suppressing the charge-up damage by connecting a protection device to a memory portion during the diffusion step (see, for example, U.S. Pat. No. 6,337,502).

FIG. 22 shows a conventional method for suppressing the charge-up damage. Referring to FIG. 22, a protection transistor 152 for the protection against the charge-up is connected to a protected device 150 such as a memory device via a wire 140. During the wiring step, if a positive charge is applied to the electrode of the protected device 150, a positive voltage is applied also to the electrode of the protection transistor 152 at the same time. Thus, the protection transistor 152 is turned ON, and the charge passes through to a substrate 141 without being accumulated at the electrode of the protected device 150. If a negative charge is applied to the protected device 150, the source/drain diffusion layer and the well diffusion layer of the protection transistor 152 are forward-biased. Therefore, the charge again passes through to the substrate 141 without being accumulated at the electrode of the protected device 150.

The term “source/drain diffusion layer” as used herein refers either one of the source diffusion layer and the drain diffusion layer of a transistor. It will be appreciated that when one of the two source/drain diffusion layers of a transistor serves as the source diffusion layer of the transistor, the other serves as the drain diffusion layer thereof.

With the conventional technique, however, the protection is not available before the wiring step. Therefore, it is not possible to protect a memory device from the charge-up during the diffusion step in the Front End Of Line (FEOL) process, which is before the wiring step. Moreover, with such a structure, a negative bias cannot be applied to the protected device after the completion of the manufacturing process.

As memory devices are more and more miniaturized, the charge-up during the diffusion step in the FEOL process has a non-negligible, serious influence on the variations of the initial threshold voltage (Vt) of memory cells, etc. For example, as a device is miniaturized, the use of a low-temperature process will be needed. Then, it will be difficult to use a heat treatment step for extracting the charge accumulated during the FEOL process. Thus, it is insufficient to protect a memory device during and after the wiring step. Moreover, the reduction in the thickness of an oxide-nitride-oxide (ONO) film to be the gate insulating film of a memory device also increases the importance of countermeasures against the charge-up during the diffusion step. For example, where the thickness of an ONO film has been decreased from 30 nm to 15 nm, if a high voltage (e.g., 10 V) is applied for a long time due to the charge-up during the diffusion step in the FEOL process, it is more likely that there occurs a charge injection that varies the initial Vt. Thus, as devices are miniaturized, the influence of the charge-up becomes more pronounced.

### SUMMARY OF THE INVENTION

The present invention has been made to solve the problem in the prior art, and has an object to realize a semiconductor device, in which a memory device is protected across positive and negative low-voltage ranges from the charge-up during the diffusion step in the FEOL process, and in which a high voltage of the positive or negative polarity necessary for driving the memory device can be applied to the memory device after the completion of the manufacturing process.

In order to solve the problem set forth above, a semiconductor device of the present invention includes a protection transistor of a first conductivity type and a protection transistor of a second conductivity type, wherein the protection transistors and the gate electrode of the protected device are connected with each other via a diffusion layer.

Specifically, a first semiconductor device of the present invention includes: a semiconductor substrate of a first conductivity type, including a first well of the first conductivity type and a second well of a second conductivity type; a protected device formed on the semiconductor substrate and including a protected device electrode; a first protection transistor formed in the second well; a second protection transistor formed in the first well; a first diffusion layer of the first conductivity type formed in the second well and being in contact with the protected device electrode; and a second diffusion layer of the first conductivity type formed in the first well. The first protection transistor includes a first gate electrode formed on the second well, and a first source/drain diffusion layer of the first conductivity type and a second source/drain diffusion layer of the first conductivity type formed in the second well on opposite sides of the first gate electrode. The second protection transistor includes a second gate electrode formed on the first well, and a third source/drain diffusion layer of the second conductivity type and a fourth source/drain diffusion layer of the second conductivity type formed in the first well on opposite sides of the second gate electrode. The fourth source/drain diffusion layer is in contact with the second diffusion layer. The third source/drain diffusion layer extends into the second well beyond the boundary between the first well and the second well, and is in contact with the second source/drain diffusion layer. The first source/drain diffusion layer is in contact with the first diffusion layer.

In the first semiconductor device, the source/drain diffusion layer of the first protection transistor and the protected device electrode are connected with each other with the first diffusion layer being interposed therebetween. Thus, it is possible to protect the protected device as early as from the FEOL process, prior to the wiring step. With the provision of the first protection transistor in the second well and the second protection transistor in the first well, a high voltage of the positive or negative polarity can be applied to the protected device after the completion of the manufacturing process.

A second semiconductor device of the present invention includes: a semiconductor substrate of a first conductivity type, including a selectively-formed deep well of a second conductivity type, a first well of the first conductivity type and a second well of the second conductivity type formed on the deep well; a protected device formed on the semiconductor substrate and including a protected device electrode; a first protection transistor formed in the first well; a first protection transistor formed in the second well; a first diffusion layer of the first conductivity type formed in the first well and being in contact with the protected device electrode; and a second diffusion layer of the first conductivity type spaced apart from the first protection transistor. The first protection transistor includes a first gate electrode formed on the first well, and a first source/drain diffusion layer of the second conductivity type and a second source/drain diffusion layer of the second conductivity type formed in the first well on opposite sides of the first gate electrode. The second protection transistor includes a second gate electrode formed on the second well, and a third source/drain diffusion layer of the first conductivity type and a fourth source/drain diffusion layer of the first conductivity type formed in the second well on opposite sides of the second gate electrode. The first source/drain diffusion layer is in contact with the first diffusion layer. The second source/drain diffusion layer is electrically connected with a region of the semiconductor substrate excluding a region where the deep well is formed with a first conductive film formed on the semiconductor substrate being interposed therebetween. The third source/drain diffusion layer is in contact with the second diffusion layer. The fourth source/drain diffusion layer is electrically connected with a region of the semiconductor substrate excluding a region where the deep well is formed with a second conductive film formed on the semiconductor substrate being interposed therebetween.

In the second semiconductor device, the source/drain diffusion layer of the first protection transistor and the protected device electrode are connected with each other with the first diffusion layer being interposed therebetween. Thus, it is possible to protect the protected device as early as from the FEOL process, prior to the wiring step. With the provision of the first protection transistor in the first well and the second protection transistor in the second well, a high voltage of the positive or negative polarity can be applied to the protected device after the completion of the manufacturing process. With the provision of the deep well of the second conductivity type, it is easy to form a diffusion layer of the second conductivity type.

A third semiconductor device of the present invention includes: a semiconductor substrate of a first conductivity type, including a selectively-formed deep well of a second conductivity type, a first well of the first conductivity type and a second well of the second conductivity type formed on the deep well; a protected device formed on the semiconductor substrate and including a protected device electrode; a first protection transistor and a second protection transistor formed in the first well; a third protection transistor formed in the second well; a first diffusion layer of the first conductivity type formed in the first well and being in contact with the protected device electrode; and a second diffusion layer of the first conductivity type formed in the first well spaced apart from the first protection transistor and the second protection transistor. The first protection transistor includes a first gate electrode formed on the first well, a first source/drain diffusion layer of the second conductivity type and a common diffusion layer of the second conductivity type formed in the first well on opposite sides of the first gate electrode. The second protection transistor includes a second gate electrode formed on the first well, a second source/drain diffusion layer of the second conductivity type and the common diffusion layer of the second conductivity type formed in the first well on opposite sides of the second gate electrode. The third protection transistor includes a third gate electrode formed on the second well, and a third source/drain diffusion layer of the first conductivity type and a fourth source/drain diffusion layer of the first conductivity type formed in the second well on opposite sides of the third gate electrode. The first source/drain diffusion layer is in contact with the first diffusion layer. The second source/drain diffusion layer is electrically connected with a region of the semiconductor substrate excluding a region where the deep well is formed with a first conductive film formed on the semiconductor substrate being interposed therebetween. The third source/drain diffusion layer is in contact with the second diffusion layer. The fourth source/drain diffusion layer is electrically connected with a region of the semiconductor substrate excluding a region where the deep well is formed with a second conductive film formed on the semiconductor substrate being interposed therebetween.

In the third semiconductor device, the source/drain diffusion layer of the first protection transistor and the protected device electrode are connected with each other with the first diffusion layer being interposed therebetween. Thus, it is possible to protect the protected device as early as from the FEOL process, prior to the wiring step. With the provision of the first protection transistor and the second protection transistor in the first well and the third protection transistor in the second well, a high voltage of the positive or negative polarity can be applied to the protected device after the completion of the manufacturing process. With the provision of the deep well of the second conductivity type, it is easy to form a diffusion layer of the second conductivity type.

A method for manufacturing the first semiconductor device of the present invention includes: a step (a) of forming a first well of a first conductivity type and a second well of a second conductivity type in a semiconductor substrate of the first conductivity type; a step (b) of forming an insulating film on the first well and on the second well; a step (c) of forming an opening in a portion of the insulating film on the second well; a step (d) of introducing an impurity into the second well through the opening to thereby form a first diffusion layer of the first conductivity type in the second well; a step (e) of forming a conductive film on the insulating film and the opening and then patterning the formed conductive film, thereby forming a first gate electrode on the second well, a second gate electrode on the first well, and a gate electrode of a protected device in contact with the first diffusion layer; a step (f) of forming a first source/drain diffusion layer of the first conductivity type and a second source/drain diffusion layer of the first conductivity type in the second well on opposite sides of the first gate electrode; a step (g) of forming a second diffusion layer of the first conductivity type in the first well; and a step (h) of forming a third source/drain diffusion layer of the second conductivity type and a fourth source/drain diffusion layer of the second conductivity type in the first well on opposite sides of the second gate electrode, wherein: the step (f) is performed so that the first source/drain diffusion layer and the first diffusion layer are connected with each other; the step (h) is performed so that the third source/drain diffusion layer extends into the second well so as to be in contact with the second source/drain diffusion layer; and the step (g) is performed so that the fourth source/drain diffusion layer and the second diffusion layer are in contact with each other.

In the method for manufacturing the first semiconductor device, the first source/drain diffusion layer and the first diffusion layer are formed so as to be in contact with each other. Thus, it is possible to protect the protected device as early as from the FEOL process, prior to the wiring step. With the provision of the first protection transistor in the second well and the second protection transistor in the first well, a high voltage of the positive or negative polarity can be applied to the protected device after the completion of the manufacturing process.

A method for manufacturing the second semiconductor device of the present invention includes: a step (a) of forming a first well of a first conductivity type and a second well of a second conductivity type in a semiconductor substrate of the first conductivity type, and forming a deep well of the second conductivity type under the first well and the second well so as to be in contact with a bottom surface of the first well and the second well; a step (b) of forming an insulating film on the first well and on the second well; a step (c) of forming an opening in a portion of the insulating film on the first well; a step (d) of introducing an impurity into the first well through the opening to thereby form a first diffusion layer of the second conductivity type in the first well; a step (e) of forming a conductive film on the insulating film and the opening and then patterning the formed conductive film, thereby forming a first gate electrode on the first well, a second gate electrode on the second well, and a protected device electrode in contact with the first diffusion layer; a step (f) of forming a first source/drain diffusion layer of the second conductivity type and a second source/drain diffusion layer of the second conductivity type in the first well on opposite sides of the first gate electrode; a step (g) of forming a third source/drain diffusion layer of the first conductivity type and a fourth source/drain diffusion layer of the first conductivity type in the second well on opposite sides of the second gate electrode, and forming a second diffusion layer of the first conductivity type in the first well so as to be in contact with the third source/drain diffusion layer; a step (h) of forming a first connection diffusion layer of the first conductivity type in the semiconductor substrate beside the first well, and forming a second connection diffusion layer of the first conductivity type beside the second well; and a step (i) of electrically connecting the second source/drain diffusion layer and the first connection diffusion layer with each other, and electrically connecting the fourth source/drain diffusion layer and the second connection diffusion layer with each other, wherein: the step (f) is performed so that the first source/drain diffusion layer and the first diffusion layer are in contact with each other; and the step (g) is performed so that the second diffusion layer is spaced apart from the first source/drain diffusion layer and the second source/drain diffusion layer.

In the method for manufacturing the second semiconductor device, the first source/drain diffusion layer and the first diffusion layer are formed so as to be in contact with each other. Thus, it is possible to protect the protected device as early as from the FEOL process, prior to the wiring step. With the provision of the first protection transistor in the first well and the second protection transistor in the second well, a high voltage of the positive or negative polarity can be applied to the protected device after the completion of the manufacturing process.

A method for manufacturing the third semiconductor device of the present invention includes: a step (a) of forming a first well of a first conductivity type and a second well of a second conductivity type in a semiconductor substrate of the first conductivity type, and forming a deep well of the second conductivity type under the first well and the second well so as to be in contact with a bottom surface of the first well and the second well; a step (b) of forming an insulating film on the first well and on the second well; a step (c) of forming an opening in a portion of the insulating film on the first well; a step (d) of introducing an impurity into the first well through the opening to thereby form a first diffusion layer of the second conductivity type in the first well; a step (e) of forming a conductive film on the insulating film and the opening and then patterning the formed conductive film, thereby forming a first gate electrode and a second gate electrode on the first well, a third gate electrode on the second well, and a protected device electrode in contact with the first diffusion layer; a step (f) of forming a common diffusion layer of the second conductivity type in the first well between the first gate electrode and the second gate electrode, forming a first source/drain diffusion layer of the second conductivity type beside the first gate electrode, and forming a second source/drain diffusion layer of the second conductivity type beside the second gate electrode; a step (g) of forming a third source/drain diffusion layer of the first conductivity type and a fourth source/drain diffusion layer of the first conductivity type in the second well on opposite sides of the third gate electrode, and forming a second diffusion layer of the first conductivity type in the first well so as to be in contact with the third source/drain diffusion layer; a step (h) of forming a first connection diffusion layer of the first conductivity type in the semiconductor substrate beside the first well, and forming a second connection diffusion layer of the first conductivity type beside the second well; and a step (i) of electrically connecting the second source/drain diffusion layer and the first connection diffusion layer with each other, and electrically connecting the fourth source/drain diffusion layer and the second connection diffusion layer with each other, wherein: the step (f) is performed so that the first source/drain diffusion layer and the first diffusion layer are in contact with each other; and the step (g) is performed so that the second diffusion layer is spaced apart from the first source/drain diffusion layer and the second source/drain diffusion layer.

In the method for manufacturing the third semiconductor device, the first source/drain diffusion layer and the first diffusion layer are formed so as to be in contact with each other. Thus, it is possible to protect the protected device as early as from the FEOL process, prior to the wiring step. With the provision of the first protection transistor in the first well and the second protection transistor in the second well, a high voltage of the positive or negative polarity can be applied to the protected device after the completion of the manufacturing process.

A method for driving the first semiconductor device of the present invention includes the steps of: applying an equal positive potential to the protected device electrode, the first gate electrode and the second well for performing an operation of injecting electrons into the protected device and an operation of reading out from the protected device; and applying a negative potential to the protected device electrode and a ground potential to the first gate electrode and the second well for performing an operation of injecting positive holes into the protected device and an operation of drawing electrons out of the protected device.

A method for driving the second semiconductor device of the present invention includes the steps of: applying a positive potential to the protected device electrode and a ground potential to the first gate electrode and the first well for performing an operation of injecting electrons into the protected device and an operation of reading out from the protected device; and applying a negative potential to the protected device electrode, the first gate electrode and the second well for performing an operation of injecting positive holes into the protected device and an operation of drawing electrons out of the protected device.

A method for driving the third semiconductor of the present invention includes the steps of: applying a positive potential to the protected device electrode and a ground potential to the first gate electrode and the first well for performing an operation of injecting electrons into the protected device and an operation of reading out from the protected device; and applying a negative potential to the protected device electrode, the first gate electrode and the second well for performing an operation of injecting positive holes into the protected device and an operation of drawing electrons out of the protected device.

### BRIEF DESCRIPTION OF THE DRAWINGS

FIGS. 1A and 1B show a semiconductor device according to a first embodiment of the present invention, wherein FIG. 1A is a plan view thereof, and FIG. 1B is a cross-sectional view thereof taken along line Ib-Ib in FIG. 1A.

FIG. 2 is a circuit diagram showing the semiconductor device according to the first embodiment of the present invention.

FIG. 3 is a cross-sectional view showing a step of a method for manufacturing the semiconductor device according to the first embodiment of the present invention.

FIG. 4 is a cross-sectional view showing a step of the method for manufacturing the semiconductor device according to the first embodiment of the present invention.

FIG. 5 is a cross-sectional view showing a step of the method for manufacturing the semiconductor device according to the first embodiment of the present invention.

FIG. 6 is a cross-sectional view showing a step of the method for manufacturing the semiconductor device according to the first embodiment of the present invention.

FIG. 7 is a cross-sectional view showing a step of the method for manufacturing the semiconductor device according to the first embodiment of the present invention.

FIGS. 8A to 8D show a semiconductor device according to a second embodiment of the present invention, wherein FIG. 8A is a plan view thereof, FIG. 8B is a cross-sectional view thereof taken along line VIIIb-VIIIb in FIG. 8A, FIG. 8C is a cross-sectional view thereof taken along line VIIIc-VIIIc in FIG. 8A, and FIG. 8D is a cross-sectional view thereof taken along line VIIId-VIIId in FIG. 8A.

FIG. 9 is a circuit diagram showing the semiconductor device according to the second embodiment of the present invention.

FIGS. 10A to 10C are cross-sectional views each showing a step of a method for manufacturing the semiconductor device according to the second embodiment of the present invention.

FIGS. 11A to 11C are cross-sectional views each showing a step of the method for manufacturing the semiconductor device according to the second embodiment of the present invention.

FIGS. 12A to 12C are cross-sectional views each showing a step of the method for manufacturing the semiconductor device according to the second embodiment of the present invention.

FIGS. 13A to 13C are cross-sectional views each showing a step of the method for manufacturing the semiconductor device according to the second embodiment of the present invention.

FIGS. 14A to 14C are cross-sectional views each showing a step of the method for manufacturing the semiconductor device according to the second embodiment of the present invention.

FIGS. 15A to 15D show a semiconductor device according to a third embodiment of the present invention, wherein FIG. 15A is a plan view thereof, FIG. 15B is a cross-sectional view thereof taken along line XVb-XVb in FIG. 15A, FIG. 15C is a cross-sectional view thereof taken along line XVc-XVc in FIG. 15A, and FIG. 15D is a cross-sectional view thereof taken along line XVd-XVd in FIG. 15A.

FIG. 16 is a circuit diagram showing the semiconductor device according to the third embodiment of the present invention.

FIGS. 17A to 17C are cross-sectional views each showing a step of a method for manufacturing the semiconductor device according to the third embodiment of the present invention.

FIGS. 18A to 18C are cross-sectional views each showing a step of the method for manufacturing the semiconductor device according to the third embodiment of the present invention.

FIGS. 19A to 19C are cross-sectional views each showing a step of the method for manufacturing the semiconductor device according to the third embodiment of the present invention.

FIGS. 20A to 20C are cross-sectional views each showing a step of the method for manufacturing the semiconductor device according to the third embodiment of the present invention.

FIGS. 21A to 21C are cross-sectional views each showing a step of the method for manufacturing the semiconductor device according to the third embodiment of the present invention.

FIG. 22 is a circuit diagram showing a conventional semiconductor device.

### DETAILED DESCRIPTION OF THE PREFERRED EMBODIMENTS

### First Embodiment

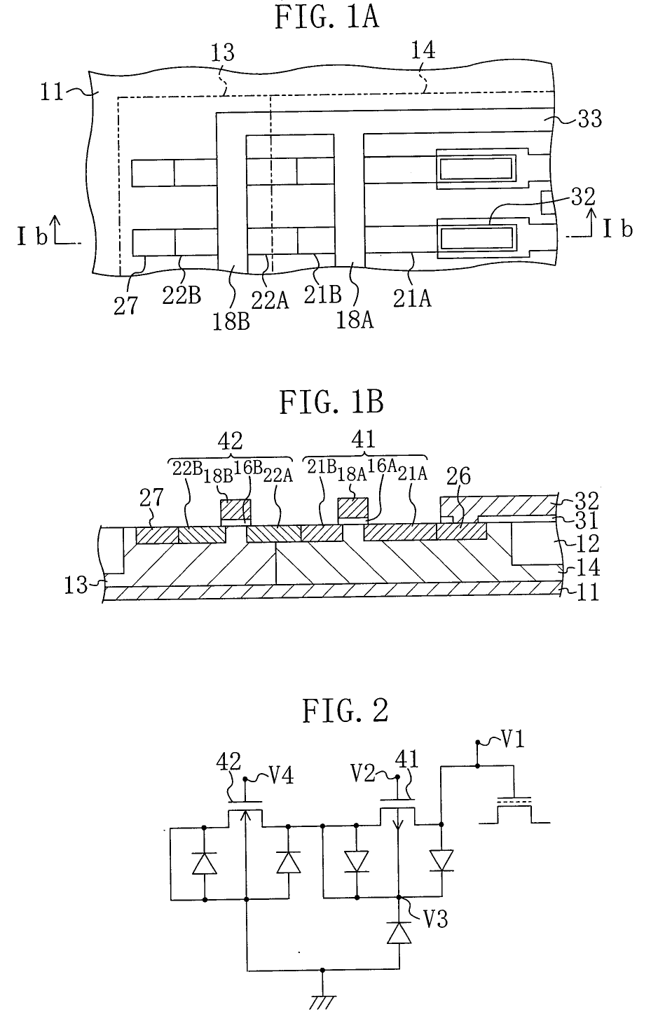

FIGS. 1A and 1B show an example of a semiconductor device according to a first embodiment of the present invention, wherein FIG. 1A shows a plan view thereof, and FIG. 1B is a cross-sectional view thereof taken along line Ib-Ib in FIG. 1A.

The semiconductor device of the present embodiment includes a memory device being a protected device, a first protection transistor 41, and a second protection transistor 42. Referring to FIGS. 1A and 1B, a first well 13 of a first conductivity type and a second well 14 of a second conductivity type are each formed in a region in a semiconductor substrate 11 of the first conductivity type that is delimited by isolation insulating films 12.

A first gate electrode 18A is formed on the second well 14 with a first gate insulating film 16A being interposed therebetween. A first source/drain diffusion layer 21A of the first conductivity type and a second source/drain diffusion layer 21B of the first conductivity type are formed in the second well 14 on opposite sides of the first gate electrode 18A.

The first source/drain diffusion layer 21A is in contact with a first diffusion layer 26 of the first conductivity type. A protected device electrode 32, being the gate electrode of the protected device, is formed on the first diffusion layer 26 with an insulating film 31 having an opening being interposed therebetween. The protected device electrode 32 is in contact with the first diffusion layer 26 through the opening.

A second gate electrode 18B is formed on the first well 13 with a second gate insulating film 16B being interposed therebetween. A third source/drain diffusion layer 22A of the second conductivity type and a fourth source/drain diffusion layer 22B of the second conductivity type are formed in the first well 13 on opposite sides of the second gate electrode 18B. The third source/drain diffusion layer 22A extends into the second well 14 beyond the boundary between the first well 13 and the second well 14, and is in contact with the second source/drain diffusion layer 21B.

A second diffusion layer 27 of the first conductivity type is formed in the first well 13 beside the fourth source/drain diffusion layer 22B. The second diffusion layer 27 and the fourth source/drain diffusion layer 22B are in contact with each other.

FIGS. 1A and 1B show a case where the first gate electrode 18A and the second gate electrode 18B are connected with each other, thereby together forming a common electrode. Then, as compared with a case where the electrodes are independent of each other, the antenna ratio is improved. Therefore, when preventing the charge-up during the manufacturing process, a voltage of the same polarity as the voltage applied to the protected device electrode 32 is more reliably applied to the first gate electrode 18A and the second gate electrode 18B. Thus, the protection effect can be obtained more stably. In FIGS. 1A and 1B, the first gate electrode 18A and the second gate electrode 18B are also connected with a dummy electrode 33 extending in parallel to the protected device electrode 32, thereby together forming a common electrode. This further improves the antenna ratio.

FIG. 2 shows an equivalent circuit of the semiconductor device of the first embodiment shown in FIGS. 1A and 1B. Referring to FIG. 2, the first protection transistor 41 and the second protection transistor 42 are connected in series with the gate electrode of the memory device being the protected device. The first protection transistor 41 is formed by the first gate electrode 18A, the first source/drain diffusion layer 21A and the second source/drain diffusion layer 21B, as shown in FIGS. 1A and 1B. The second protection transistor 42 is formed by the second gate electrode 18B, the third source/drain diffusion layer 22A and the fourth source/drain diffusion layer 22B. A PN junction diode is formed between each diffusion layer and a well, and between a well and the semiconductor substrate.

Next, a method for driving the semiconductor device of the present embodiment will be described with reference to FIGS. 1A, 1B and 2 and Table 1 below. It is assumed in the following description that the protected device electrode is the terminal V1, the first gate electrode is the terminal V2, the second well is the terminal V3, and the second gate electrode is the terminal V4.

TABLE 1

| | V1 | V2 | V3 | V4 |
|---|---|---|---|---|
| Positive charge | positive | positive | open | positive |
| during process | | | | |
| Negative charge | negative | negative | open | negative |
| during process | | | | |
| Write | 9 | 9 | 9 | 0 |
| Erase | −6 | 0 | 0 | 0 |
| Read | 5 | 5 | 5 | 0 |

If a positive charge-up occurs during the manufacturing process, including before the wiring step, a positive voltage is applied to the terminal V1, the terminal V2 and the terminal V4 as shown in Table 1, thus turning ON the second protection transistor 42. Then, the charge passes through to the semiconductor substrate 11 via the protected device electrode 32, the first diffusion layer 26, the second well 14, the third source/drain diffusion layer 22A, the fourth source/drain diffusion layer 22B and the second diffusion layer 27. Thus, it is possible to suppress the charge injection into the memory device or the charge drawing out of the memory device.

More specifically, the junction between the protected device electrode 32 and the first diffusion layer 26 is substantially a metal junction, and the potential difference therebetween is substantially 0 V. The junction between the first diffusion layer 26 and the second well 14 is a forward-biased PN junction, and the potential difference therebetween is about 0.7 V. Since the second well 14 and the third source/drain diffusion layer 22A are of the same conductivity type, the potential difference therebetween is substantially 0 V. Since the second protection transistor 42 is ON, the potential difference between the third source/drain diffusion layer 22A and the fourth source/drain diffusion layer 22B is substantially 0 V. The junction between the fourth source/drain diffusion layer 22B and the second diffusion layer 27 has a metal silicide shunt structure, whereby the potential difference therebetween is substantially 0 V. Therefore, it is possible to suppress the overall positive charge-up during the manufacturing process to about 1 V.

If a negative charge-up occurs during the manufacturing process, including before the wiring step, a negative voltage is applied to the terminal V1, the terminal V2 and the terminal V4, as shown in Table 1, thus turning ON the first protection transistor 41. Then, the charge passes through to the semiconductor substrate 11 via the protected device electrode 32, the first diffusion layer 26, the first source/drain diffusion layer 21A, the second source/drain diffusion layer 21B, the third source/drain diffusion layer 22A and the first well 13. Thus, it is possible to suppress the charge injection into the memory device or the charge drawing out of the memory device.

More specifically, the junction between the protected device electrode 32 and the first diffusion layer 26 and the first source/drain diffusion layer 21A is substantially a metal junction, and the potential difference therebetween is substantially 0 V. Since the first protection transistor 41 is ON, the potential difference between the first source/drain diffusion layer 21A and the second source/drain diffusion layer 21B is substantially 0 V. The junction between the second source/drain diffusion layer 21B and the third source/drain diffusion layer 22A has a metal silicide shunt structure, whereby the potential difference therebetween is substantially 0 V. The junction between the third source/drain diffusion layer 22A and the first well 13 is a forward-biased PN junction, and the potential difference therebetween is about 0.7 V. Therefore, it is possible to suppress the overall negative charge-up during the manufacturing process to about 1 V.

Preferably, the antenna ratios of the terminal V1, the terminal V2 and the terminal V4 are set to be about equal to one another or so that those of the terminal V2 and the terminal V4 are greater than that of the terminal V1. Then, even when a small charge is applied to the protected device, the voltage applied to the first protection transistor 41 and the second protection transistor 42 exceeds the threshold voltage, thereby turning ON the first protection transistor 41 and the second protection transistor 42.

When injecting electrons into the memory device after the completion of the manufacturing process, 9 V, for example, can be applied to each of the terminal V1, the terminal V2 and the terminal V3, as shown in Table 1, to thereby apply an intended voltage to the memory device without activating the protection device. Thus, the operation of injecting electrons into the memory device is realized. Then, by applying a voltage at the same time to a bit line of the memory device and a well of the memory device, it is possible to realize various electron injecting operations such as the Channel Hot Electron (CHE) current and the Fowler-Nordheim (FN) current.

When reading out a current from the memory device after the completion of the manufacturing process, 5 V, for example, can be applied to each of the terminal V1, the terminal V2 and the terminal V3, as shown in Table 1, to thereby apply an intended voltage to the memory device without activating the protection device. Thus, the operation of reading out a current from the memory device is realized. Then, by applying a voltage at the same time to a bit line of the memory device and a well of the memory device, it is possible to adjust the read characteristics.

When drawing electrons out of, or injecting positive holes into, the memory device after the completion of the manufacturing process, −6 V, for example, can be applied to the terminal V1 and 0 V, for example, can be applied to each of the terminal V2 and the terminal V3, as shown in Table 1, to thereby apply an intended voltage to the memory device without activating the protection device. Thus, the operation of drawing electrons out of, or injecting positive holes into, the memory device is realized. Then, by applying a voltage at the same time to a bit line of the memory device and a well of the memory device, it is possible to realize various electron drawing or positive hole injecting operations such as the Band To Band Tunneling (BTBT) current and the FN current.

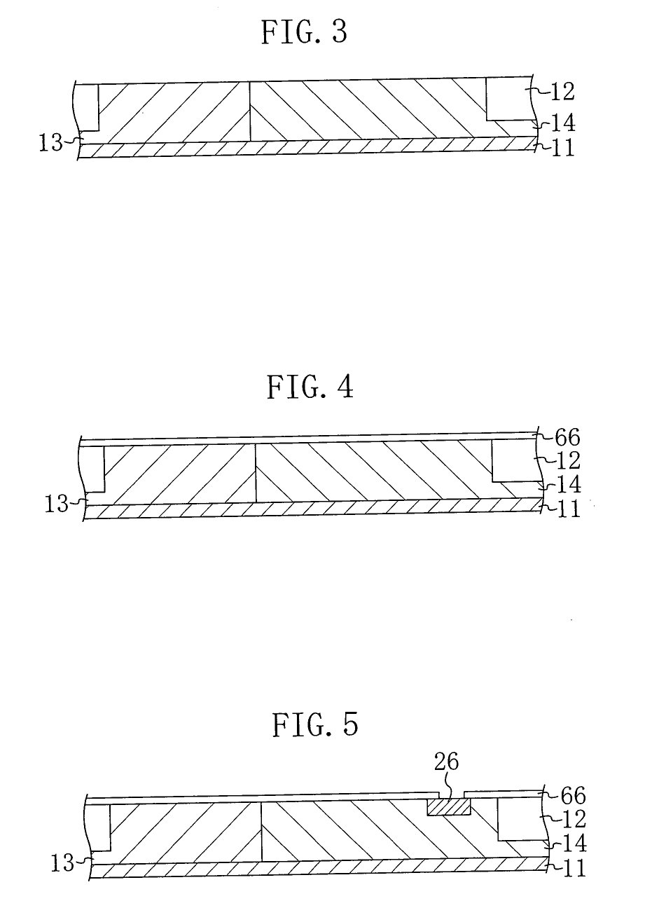

An example of a method for manufacturing the semiconductor device of the present embodiment will now be described. First, referring to FIG. 3, the isolation insulating film 12, the first well 13 of the first conductivity type and the second well 14 of the second conductivity type are each formed in a predetermined region on the semiconductor substrate 11 of the first conductivity type, thus defining a memory device region in which the memory device being the protected device is to be formed, a first protection transistor region in which the first protection transistor is to be formed, and a second protection transistor region in which the second protection transistor is to be formed.

Then, referring to FIG. 4, an insulating film 66 having a thickness of 2 nm to 30 nm is formed across the memory device region, the first protection transistor region and the second protection transistor region. Although the insulating film 66 is a single-piece film in the illustrated example, independent films may be formed separately for the memory device region, the first protection transistor region and the second protection transistor region. The insulating film 66 will later be the gate insulating film.

Then, referring to FIG. 5, an opening is formed in the insulating film 66 in the memory device region. Then, an impurity of the first conductivity type is injected at a dose of 1×10¹⁵/cm², for example, into the second well 14 through the opening, thereby forming the first diffusion layer 26 of the first conductivity type. Instead of using such a method, the impurity of the first conductivity type may be injected via the insulating film 66 during an injection process for setting the threshold (Vt) of peripheral transistors, for example.

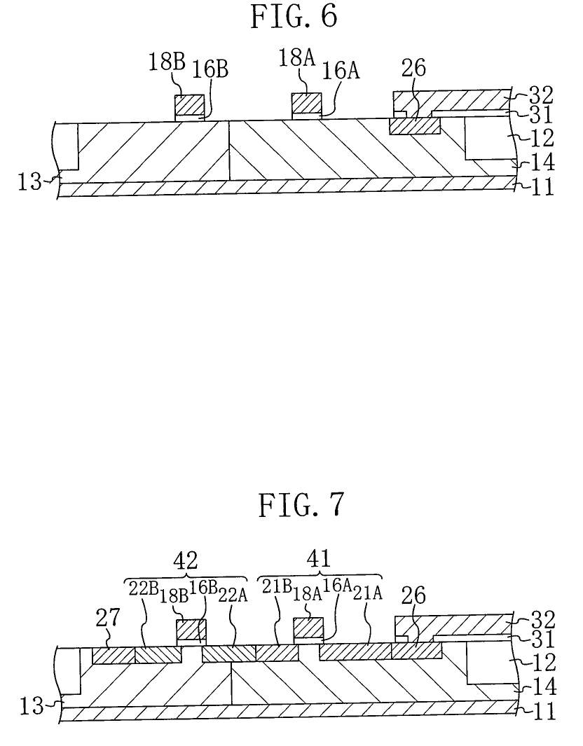

Then, referring to FIG. 6, the protected device electrode 32 being the gate electrode of the memory device is formed in the memory device region, the first gate electrode 18A is formed in the first protection transistor region, and the second gate electrode 18B is formed in the second protection transistor region. Through the heat treatment in this step, the extent of distribution of the first diffusion layer 26 grows larger than immediately after the injection. The protected device electrode 32 may be formed so as to be in direct contact with the first diffusion layer 26 through the opening. Alternatively, there may exist an insulating film having a thickness of 4 nm or less at the interface therebetween. If the thickness of such an insulating film is 4 nm or less, the protected device electrode 32 and the first diffusion layer 26 are bonded together substantially in metallic bonding, and it is possible to ensure a sufficient electric connection between the protected device electrode 32 and the first diffusion layer 26. The presence of an insulating film having a thickness of 4 nm or less reduces the possibility of abnormal Si growth from the substrate, thereby increasing the process stability.

The protected device electrode 32 may have a two-layer structure including an upper layer and a lower layer. In such a case, the lower layer of the electrode is first deposited, and then a region at least including the opening is etched away. Then, an impurity of the first conductivity type is injected through the opening to form the first diffusion layer, and then an upper layer of the electrode is further deposited thereon. Thus, through the opening, the upper layer of the electrode and the first diffusion layer are connected with each other directly or indirectly with an insulating film having a thickness of 4 nm or less being interposed therebetween.

Then, referring to FIG. 7, an impurity of the first conductivity type is injected at a dose of 1×10¹⁵/cm², for example, into regions of the second well 14 on opposite sides of the first gate electrode 18A. Thus, the first source/drain diffusion layer 21A and the second source/drain diffusion layer 21B are formed on opposite sides of the first gate electrode 18A. In this process, the ion implantation is performed so that the first source/drain diffusion layer 21A and the first diffusion layer 26 are in contact with each other. Moreover, an impurity of the second conductivity type is injected at a dose of 1×10¹⁵/cm², for example, into regions of the first well 13 on opposite sides of the second gate electrode 18B. Thus, the third source/drain diffusion layer 22A and the fourth source/drain diffusion layer 22B are formed on opposite sides of the second gate electrode 18B. This process is performed so that the third source/drain diffusion layer 22A extends into the second well 14 so as to be in contact with the second source/drain diffusion layer 21B. Moreover, an impurity of the first conductivity type is injected into the first well 13 to form the second diffusion layer 27 so that the second diffusion layer 27 is in contact with the fourth source/drain diffusion layer 22B. The order in which the impurity injection processes are performed is not limited to any particular order. Impurity injection processes of the same conductivity type may be combined together.

For each of the protected device, the first protection transistor and the second protection transistor, a sidewall may be formed beside the gate electrode, or an extension region, or the like, may be provided in the diffusion layer.

Preferably, a metal silicide layer is formed over the first source/drain diffusion layer 21A, the second source/drain diffusion layer 21B, the third source/drain diffusion layer 22A, the fourth source/drain diffusion layer 22B and the second diffusion layer 27. Where there is no metal silicide layer, the connection between the second source/drain diffusion layer 21B of the first conductivity type and the third source/drain diffusion layer 22A of the second conductivity type and the connection between the fourth source/drain diffusion layer 22B of the second conductivity type and the second diffusion layer 27 of the first conductivity type are made by utilizing the peak inverse voltage of a PN junction between high-concentration diffusion layers being low under a reverse bias. Nevertheless, by forming the metal silicide layer, there is obtained a direct metal junction, thus improving the connectivity, whereby it is possible to bring the charge-up protection voltage range during the manufacturing process to a lower voltage range.

As described above, with the semiconductor device of the present embodiment, the effect of protecting the protected device can be exerted as early as from the FEOL process, whereas the effect was exerted only at and after the wiring step with the conventional technique.

Moreover, while a negative voltage cannot be applied to the protected device after the completion of the manufacturing process with the structure of the conventional technique, the semiconductor device of the present embodiment allows for the application of a high voltage of the positive or negative polarity to the protected device after the completion of the manufacturing process.

In the present embodiment, the gate electrode of the memory device being the protected device is connected with the source/drain diffusion layer of the first protection transistor via the first diffusion layer, thereby exerting the protection effect as early as from the FEOL process. However, it is also effective to employ a structure where the gate electrode of the memory device and the source/drain diffusion layer of the first protection transistor are connected with each other through a wiring step similar to that of the conventional technique. Although the protected device is then protected at and after the wiring step, it is possible to apply a high voltage of the negative polarity to the memory device for driving the memory device after the completion of the manufacturing process, and it is possible to reduce the number of steps in the manufacturing process and to decrease the level of difficulty of the manufacturing process because diffusion layers in the substrate are not directly connected with each other.

### Second Embodiment

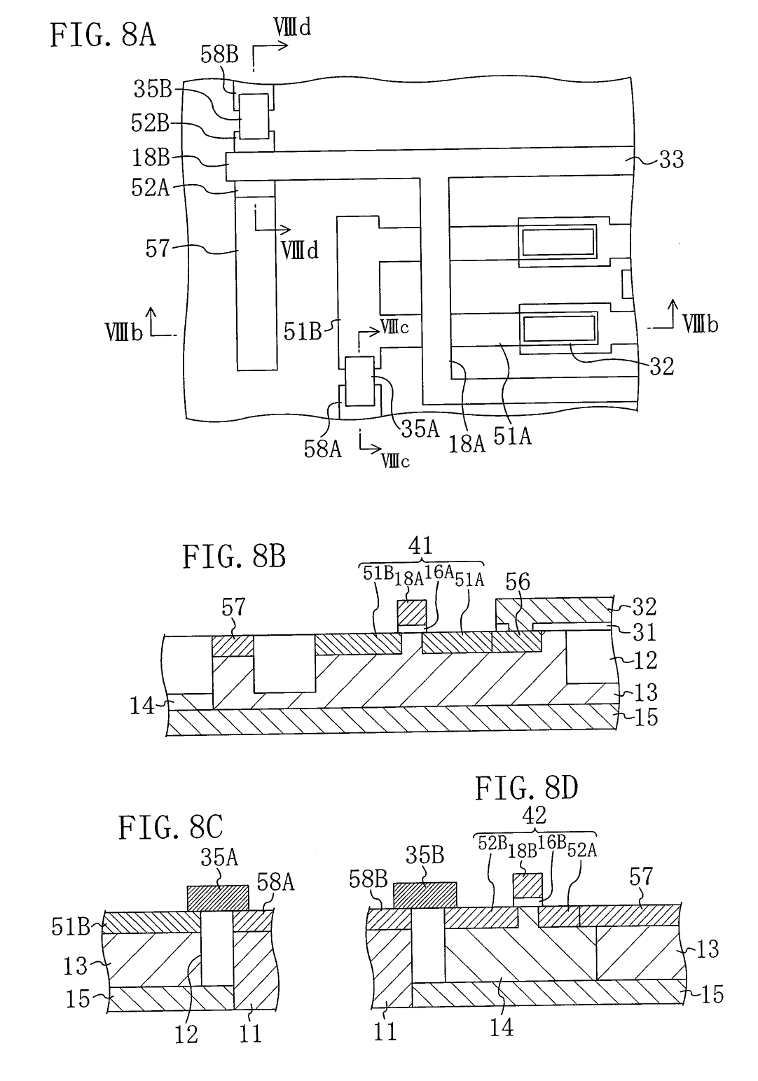

A second embodiment of the present invention will now be described with reference to the drawings. FIGS. 8A to 8D show an example of a semiconductor device according to the second embodiment of the present invention, wherein FIG. 8A is a plan view thereof, FIG. 8B is a cross-sectional view thereof taken along line VIIIb-VIIIb in FIG. 8A, FIG. 8C is a cross-sectional view thereof taken along line VIIIc-VIIIc in FIG. 8A, and FIG. 8D is a cross-sectional view thereof taken along line VIIId-VIIId in FIG. 8A.

The semiconductor device of the present embodiment includes a memory device being a protected device, a first protection transistor, and a second protection transistor. Referring to FIGS. 8A to 8D, in the semiconductor device of the present embodiment, a deep well 15 of the second conductivity type is formed in the semiconductor substrate 11 of the first conductivity type. The first well 13 of the first conductivity type and the second well 14 of the second conductivity type are formed on the deep well 15.

The first protection transistor 41 is formed in the first well 13. The first protection transistor 41 includes the first gate insulating film 16A and the first gate electrode 18A, which are formed in this order on the first well 13, and a first source/drain diffusion layer 51A of the second conductivity type and a second source/drain diffusion layer 51B of the second conductivity type, which are formed in the first well 13 on opposite sides the first gate electrode 18A.

The first source/drain diffusion layer 51A is in contact with a first diffusion layer 56 of the first conductivity type. The protected device electrode 32, being the gate electrode of the protected device, is formed on the first diffusion layer 56 with the insulating film 31 having an opening being interposed therebetween. The protected device electrode 32 is in contact with the first diffusion layer 56 through the opening.

A second diffusion layer 57 of the first conductivity type is formed in a region of the first well 13 that is delimited by the isolation insulating films 12.

The second protection transistor 42 is formed in the second well 14. The second protection transistor 42 includes the second gate insulating film 16B and the second gate electrode 18B, which are formed in this order on the second well 14, and a third source/drain diffusion layer 52A of the first conductivity type and a fourth source/drain diffusion layer 52B of the first conductivity type, which are formed in the second well 14 on opposite sides of the second gate electrode 18B. The third source/drain diffusion layer 52A is in contact with the second diffusion layer 57.

A first connection diffusion layer 58A of the first conductivity type and a second connection diffusion layer 58B of the first conductivity type are formed each in a region of the semiconductor substrate 11 that is isolated by the isolation insulating film 12 from the region of the deep well 15. The first connection diffusion layer 58A and the second source/drain diffusion layer 51B are electrically connected with each other by a first conductive film 35A, being a connection electrode, and the second connection diffusion layer 58B and the fourth source/drain diffusion layer 52B are electrically connected with each other by a second conductive film 35B.

FIGS. 8A to 8D show a case where the first gate electrode 18A and the second gate electrode 18B are connected with each other, thereby together forming a common electrode. Then, as compared with a case where the electrodes are independent of each other, the antenna ratio is improved. Therefore, when preventing the charge-up during the manufacturing process, a voltage of the same polarity as the voltage applied to the protected device electrode 32 is more reliably applied to the first gate electrode 18A and the second gate electrode 18B. Thus, the protection effect can be obtained more stably. Moreover, referring to FIGS. 8A to 8D, the first gate electrode 18A and the second gate electrode 18B are connected with the dummy electrode 33 extending in parallel to the protected device electrode 32, thereby together forming a common electrode. This further improves the antenna ratio.

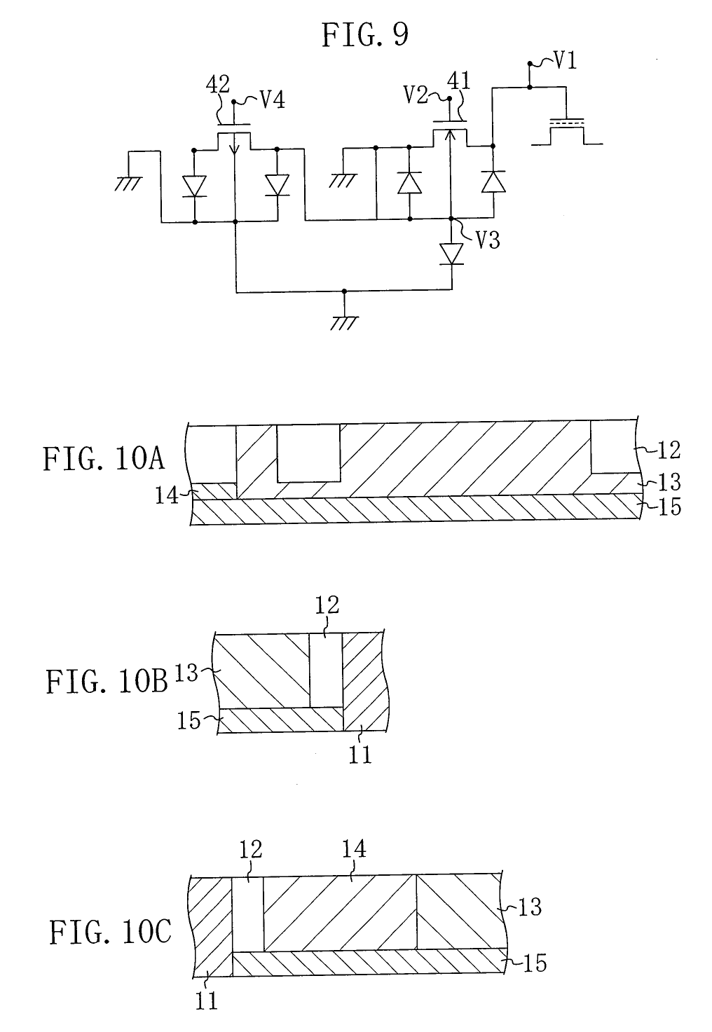

FIG. 9 shows an equivalent circuit of the semiconductor device shown in FIGS. 8A to 8D. Referring to FIG. 9, the first protection transistor 41 and the second protection transistor 42 are connected in series with the gate electrode of the memory device being the protected device. The first protection transistor 41 is formed by the first gate electrode 18A, the first source/drain diffusion layer 51A and the second source/drain diffusion layer 51B, as shown in FIGS. 8A to 8D. The second protection transistor 42 is formed by the second gate electrode 18B, the third source/drain diffusion layer 52A and the fourth source/drain diffusion layer 52B. A PN junction diode is formed between each diffusion layer and a well, and between a well and the semiconductor substrate.

Next, a method for driving the semiconductor device of the present embodiment will be described with reference to FIGS. 8A to 8D and 9 and Table 2 below. It is assumed in the following description that the protected device electrode is the terminal V1, the first gate electrode is the terminal V2, the second well is the terminal V3, and the second gate electrode is the terminal V4.

TABLE 2

| | V1 | V2 | V3 | V4 |
|---|---|---|---|---|
| Positive charge | positive | positive | open | positive |
| during process | | | | |
| Negative charge | negative | negative | open | negative |
| during process | | | | |
| Write | 9 | 0 | 0 | 0 |
| Erase | −6 | −6 | −6 | −6 |
| Read | 5 | 0 | 0 | 0 |

If a positive charge-up occurs during the manufacturing process, including before the wiring step, a positive voltage is applied to the terminal V1, the terminal V2 and the terminal V4 as shown in Table 2, thus turning ON the first protection transistor 41. Then, the charges passes through to the semiconductor substrate 11 via the protected device electrode 32, the first diffusion layer 56, the first source/drain diffusion layer 51A, the second source/drain diffusion layer 51B, the first conductive film 35A and the first connection diffusion layer 58A. Thus, it is possible to suppress the charge injection into the memory device being the protected device or the charge drawing out of the memory device.

More specifically, the junction between the protected device electrode 32 and the first diffusion layer 56 is substantially a metal junction, and the potential difference therebetween is substantially 0 V. Since the first protection transistor 41 is ON, the potential difference between the first source/drain diffusion layer 51A and the second source/drain diffusion layer 51B is substantially 0 V. Moreover, since the junction between the second source/drain diffusion layer 51B and the semiconductor substrate 11 is substantially a metal junction, the potential difference therebetween is substantially 0 V. Therefore, it is possible to suppress the overall positive charge-up during the manufacturing process to about 1 V.

If a negative charge-up occurs during the manufacturing process, including before the wiring step, a negative voltage is applied to the terminal V1, the terminal V2 and the terminal V4, as shown in Table 2, thus turning ON the second protection transistor 42. Then, the charge passes through to the semiconductor substrate 11 via the protected device electrode 32, the first diffusion layer 56, the first well 13, the second diffusion layer 57, the third source/drain diffusion layer 52A, the second conductive film 35B and the second connection diffusion layer 58B. Thus, it is possible to suppress the charge injection into the memory device or the charge drawing out of the memory device.

More specifically, the junction between the protected device electrode 32 and the first diffusion layer 56 is substantially a metal junction, and the potential difference therebetween is substantially 0 V. The junction between the first diffusion layer 56 and the first well 13 is a forward-biased PN junction, and the potential difference therebetween is about 0.7 V. Since the second protection transistor 42 is ON, the potential difference between the third source/drain diffusion layer 52A and the fourth source/drain diffusion layer 52B is 0 V. Since the junction between the fourth source/drain diffusion layer 52B and the semiconductor substrate 11 is substantially a metal junction, the potential difference therebetween is substantially 0 V. Therefore, it is possible to suppress the overall negative charge-up during the manufacturing process to about 1 V.

Preferably, the antenna ratios of the terminal V1, the terminal V2 and the terminal V4 are set to be about equal to one another or so that those of the terminal V2 and the terminal V4 are greater than that of the terminal V1. Then, even when a small charge is applied to the protected device, the voltage applied to the first protection transistor 41 and the second protection transistor 42 exceeds the threshold voltage, thereby turning ON the first protection transistor 41 and the second protection transistor 42. When injecting electrons into the memory device after the completion of the manufacturing process, 9 V, for example, can be applied to the terminal V1 and 0 V, for example, can be applied to each of the terminal V2 and the terminal V3, as shown in Table 2, to thereby apply an intended voltage to the memory device without activating the protection device. Thus, the operation of injecting electrons into the memory device is realized. Then, by applying a voltage at the same time to a bit line of the memory device and a well of the memory device, it is possible to realize various electron injecting operations such as the CHE current and the FN current.

When reading out a current from the memory device after the completion of the manufacturing process, 5 V can be applied to the terminal V1 and 0 V can be applied to each of the terminal V2 and the terminal V3, as shown in Table 2, to thereby apply an intended voltage to the memory device without activating the protection device. Thus, is the operation of reading out a current from the memory device is realized. Then, by applying a voltage at the same time to a bit line of the memory device and a well of the memory device, it is possible to adjust the read characteristics.

When drawing electrons out of, or injecting positive holes into, the memory device after the completion of the manufacturing process, −6 V can be applied to each of the terminal V1, the terminal V2 and the terminal V3, as shown in Table 2, to thereby apply an intended voltage to the memory device without activating the protection device. Thus, the operation of drawing electrons out of, or injecting positive holes into, the memory device is realized. Then, by applying a voltage at the same time to a bit line of the memory device and a well of the memory device, it is possible to realize various electron drawing or positive hole injecting operations such as the BTBT current and the FN current.

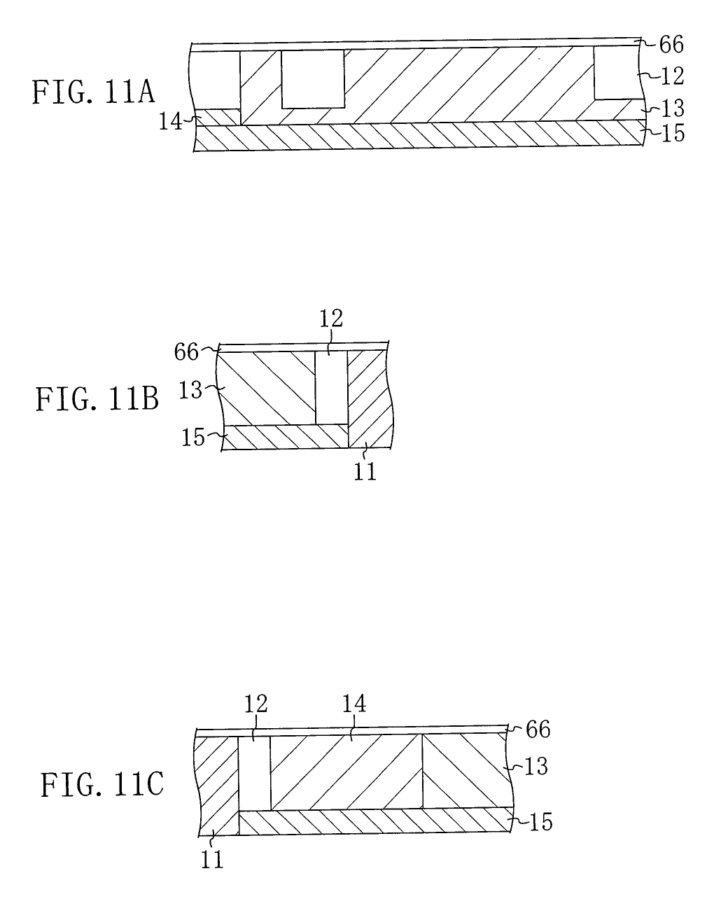

An example of a method for manufacturing the semiconductor device of the second embodiment will now be described with reference to the drawings. FIGS. 10A to 14C show a sequence of steps in the method for manufacturing the semiconductor device of the second embodiment. FIGS. 10A, 11A, 12A, 13A and 14A show cross-sectional views taken along line VIIIb-VIIIb in FIG. 8A, FIGS. 10B, 11B, 12B, 13B and 14B show cross-sectional views taken along line VIIIc-VIIIc, and FIGS. 10C, 11C, 12C, 13C and 14C show cross-sectional views taken along line VIIId-VIIId.

First, referring to FIGS. 10A to 10C, the isolation insulating film 12, the first well 13 of the first conductivity type, the second well 14 of the first conductivity type, and the deep well 15 of the second conductivity type are each formed in a predetermined region of the semiconductor substrate 11 of the first conductivity type, thus defining a memory device region, a first protection transistor region and a second protection transistor region.

Then, referring to FIGS. 11A to 11C, the insulating film 66 having a thickness of 2 nm to 30 nm is formed across the memory device region, the first protection transistor region and the second protection transistor region. The insulating film 66 may be a single piece of film provided across the memory device region, the first protection transistor region and the second protection transistor region, or may be a group of pieces of film provided independently for the regions.

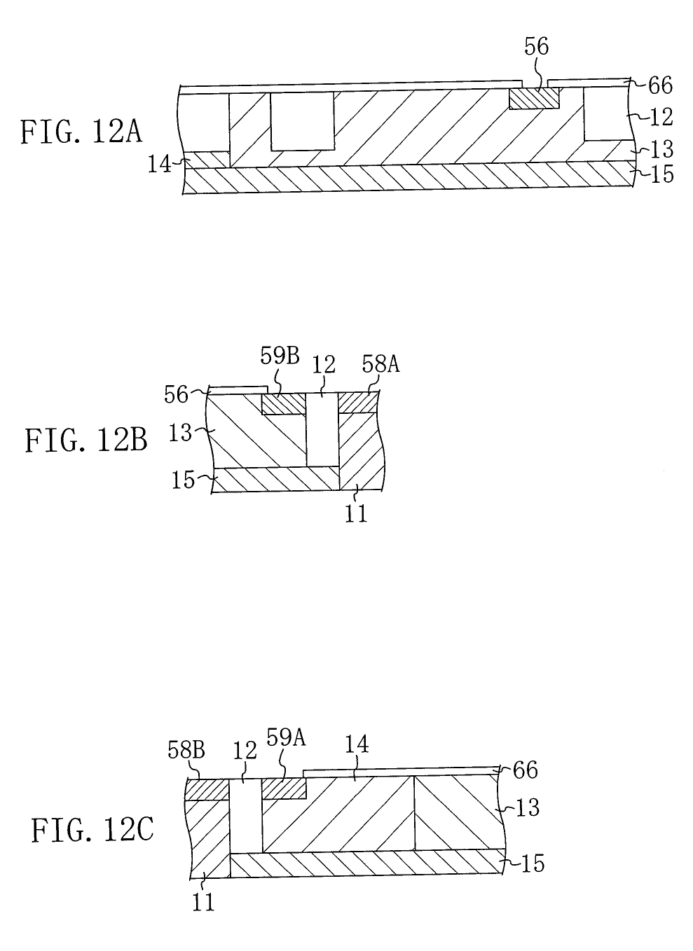

Then, referring to FIGS. 12A to 12C, an opening is formed in an area of the memory device region by removing a portion of the insulating film 66. Then, an impurity of the second conductivity type is injected at a dose of 1×10¹⁵/cm², for example, into the first well 13 through the opening, thereby forming the first diffusion layer 56. Instead of using such a method, the impurity of the second conductivity type may be injected via the insulating film 66 during an injection process for setting the threshold (Vt) of peripheral transistors, for example.

Then, the insulating film 66 is removed selectively, and an impurity of the first conductivity type is injected at a dose of 1×10¹⁵/cm², for example, thereby forming the first connection diffusion layer 58A in a region of the semiconductor substrate 11 that is outside the region of the deep well 15 and that is adjacent to the first well 13 with the isolation insulating film 12 being interposed therebetween, and forming the second connection diffusion layer 58B in a region that is adjacent to the second well 14 with the isolation insulating film 12 being interposed therebetween. A first conductivity type diffusion layer 59A is formed in a region of the second well 14 that is opposing the second connection diffusion layer 58B with the isolation insulating film 12 being interposed therebetween. The first conductivity type diffusion layer 59A is later to be integral with the fourth source/drain diffusion layer 52B. An impurity of the second conductivity type is injected at a dose of 1×10¹⁵/cm², for example, thereby forming a second conductivity type diffusion layer 59B in a region of the first well 13 that is opposing the first connection diffusion layer 58A with the isolation insulating film 12 being interposed therebetween. The second conductivity type diffusion layer 59B is later to be integral with the second source/drain diffusion layer 51B.

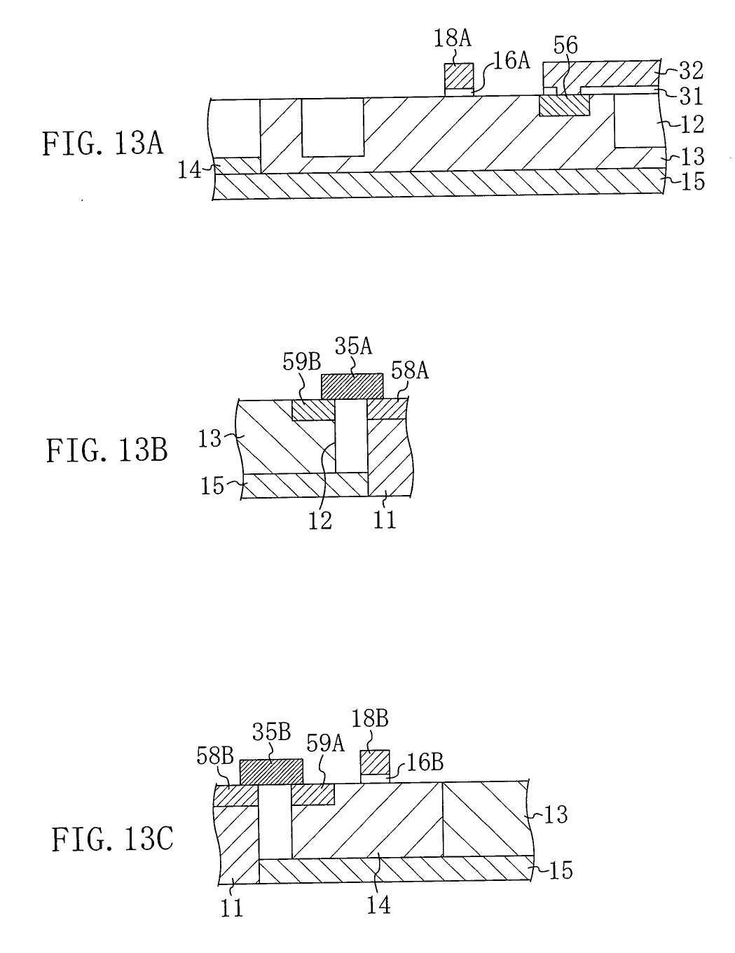

Then, Referring to FIGS. 13A to 13C, the protected device electrode 32 being the gate electrode of the memory device is formed in the memory device formation region, the first gate electrode 18A in the first protection transistor formation region, and the second gate electrode 18B in the second protection transistor region. Moreover, the first conductive film 35A and the second conductive film 35B are formed. The first conductive film 35A extends over the isolation insulating film 12 to electrically connect the second conductivity type diffusion layer 59B and the first connection diffusion layer 58A with each other, and the second conductive film 35B extends over the isolation insulating film 12 to electrically connect the first conductivity type diffusion layer 59A and the second connection diffusion layer 58B with each other. Through the heat treatment in this step, the extent of distribution of the first diffusion layer 56 grows larger than immediately after the injection. The protected device electrode 32 may be formed so as to be in direct contact with the first diffusion layer 56 through the opening. Alternatively, there may exist an insulating film having a thickness of 4 nm or less at the interface therebetween. If the thickness of such an insulating film is 4 nm or less, the protected device electrode 32 and the first diffusion layer 56 are bonded together substantially in metallic bonding, and it is possible to ensure a sufficient electric connection between the protected device electrode 32 and the first diffusion layer 56. The presence of an insulating film having a thickness of 4 nm or less reduces the possibility of abnormal Si growth from the substrate, thereby increasing the process stability.

The protected device electrode 32 may have a two-layer structure including an upper layer and a lower layer. In such a case, the lower layer of the electrode is first deposited, and then a region at least including the opening is etched away. Then, an impurity of the first conductivity type is injected through the opening to form the first diffusion layer, and then an upper layer of the electrode is further deposited thereon. Thus, through the opening, the upper layer of the electrode and the first diffusion layer are connected with each other directly or indirectly with an insulating film having a thickness of 4 nm or less being interposed therebetween.

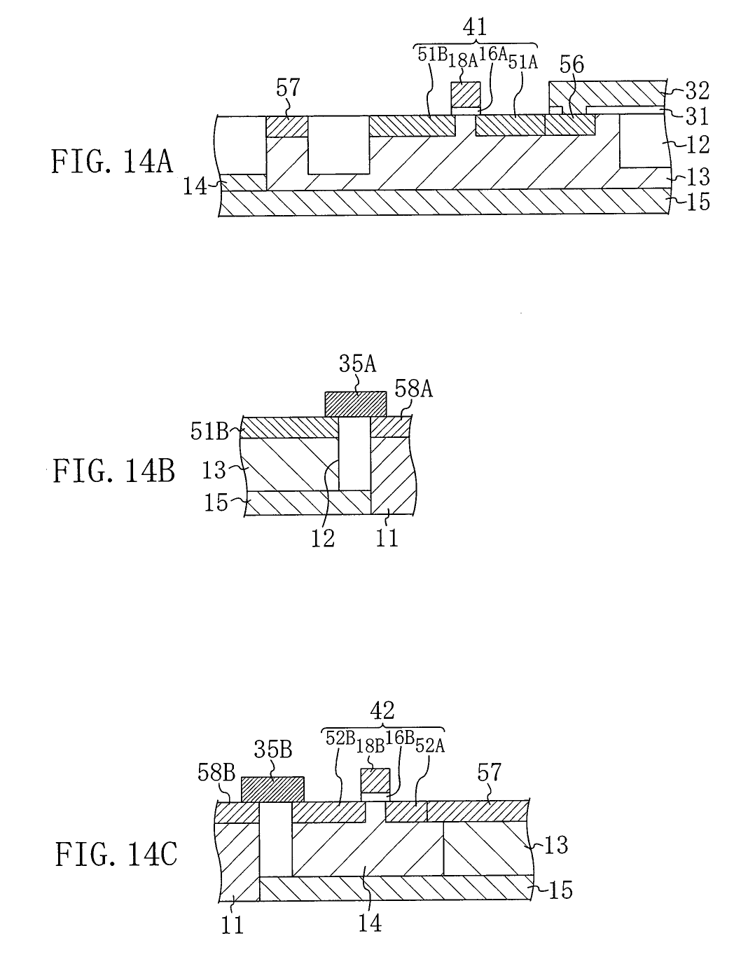

Then, referring to FIGS. 14A to 14C, an impurity of the second conductivity type is injected at a dose of 1×10¹⁵/cm², for example, into regions of the first well 13 on opposite sides of the first gate electrode 18A. Thus, the first source/drain diffusion layer 51A and the second source/drain diffusion layer 51B are formed on opposite sides of the first gate electrode 18A. In this process, the ion implantation is performed so that the first source/drain diffusion layer 51A and the first diffusion layer 56 are in contact with each other. Moreover, the ion implantation is performed so that the second source/drain diffusion layer 51B and the second conductivity type diffusion layer 59B are in contact with, and integral with, each other. Thus, the second source/drain diffusion layer 51B is connected with the semiconductor substrate 11 via the first conductive film 35A and the first connection diffusion layer 58A.

Moreover, an impurity of the first conductivity type is injected at a dose of 1×10¹⁵/cm², for example, into regions of the second well 14 on opposite sides of the second gate electrode 18B. Thus, the third source/drain diffusion layer 52A and the fourth source/drain diffusion layer 52B are formed on opposite sides of the second gate electrode 18B. This process is performed so that the fourth source/drain diffusion layer 52B and the first conductivity type diffusion layer 59A are in contact with, and integral with, each other. Thus, the fourth source/drain diffusion layer 52B is connected with the semiconductor substrate 11 via the second conductive film 35B and the second connection diffusion layer 58B.

Moreover, an impurity of the first conductivity type is injected into the first well 13 so as to form the second diffusion layer 57 isolated from the second source/drain diffusion layer 51B. In this process, the second diffusion layer 57 is formed on the first well 13 and the second well 14 so as to be in contact with the third source/drain diffusion layer 52A over the second well 14. The order in which the impurity injection processes are performed is not limited to any particular order. Impurity injection processes of the same conductivity type may be combined together.

Instead of using the isolation insulating film 12 for the isolation between the second source/drain diffusion layer 51B and the semiconductor substrate 11, the isolation may be provided by a diffusion layer of the first conductivity type. In such a case, instead of using the first conductive film 35A on the isolation insulating film 12 for the connection between the second source/drain diffusion layer 51B and the semiconductor substrate 11, the connection may be made by a metal silicide shunt structure formed on the semiconductor substrate 11. In such a case, the first connection diffusion layer 58A and the second conductivity type diffusion layer 59B do not need to be formed in the manufacturing process as described above, and the dose may be about 1×10¹⁴/cm².

The isolation between the fourth source/drain diffusion layer 52B and the semiconductor substrate 11 may be provided also by a diffusion layer, wherein the connection therebetween is made by a metal silicide shunt structure formed on the semiconductor substrate 11.

For each of the protected device, the first protection transistor and the second protection transistor, a sidewall may be formed beside the gate electrode, or an extension region, or the like, may be provided in the diffusion layer.

A metal silicide layer may be formed over the first source/drain diffusion layer 51A, the second source/drain diffusion layer 51B, the third source/drain diffusion layer 52A, the fourth source/drain diffusion layer 52B and the second diffusion layer 57. This increases the drive capability of each protection transistor, thereby improving the effect of shunting the current in case of a charge-up during the manufacturing process.

As described above, with the semiconductor device of the present embodiment, the effect of protecting the protected device can be exerted as early as from the FEOL process, whereas the effect was exerted only at and after the wiring step with the conventional technique.

Moreover, while a negative voltage cannot be applied to the protected device after the completion of the manufacturing process with the structure of the conventional technique, the semiconductor device of the present embodiment allows for the application of a high voltage of the positive or negative polarity to the protected device after the completion of the manufacturing process.

In the present embodiment, the gate electrode of the memory device being the protected device is connected with the source/drain diffusion layer of the first protection transistor via the first diffusion layer, thereby exerting the protection effect as early as from the FEOL process. However, it is also effective to employ a structure where the gate electrode of the memory device and the source/drain diffusion layer of the first protection transistor are connected with each other through a wiring step similar to that of the conventional technique. Although the protected device is then protected at and after the wiring step, it is possible to apply a high voltage of the negative polarity to the memory device for driving the memory device after the completion of the manufacturing process, and it is possible to reduce the number of steps in the manufacturing process and to decrease the level of difficulty of the manufacturing process because diffusion layers in the substrate are not directly connected with each other.

With the semiconductor device of the second embodiment, a larger layout area is required for the formation of the protection structure, as compared with the first embodiment, but the impurity diffusion layer of the second conductivity type can be formed easily. Specifically, where the memory device being the protected device is a non-volatile memory using a two-layer electrode including an upper layer and a lower layer, the injection for the source/drain section of the memory device using the lower layer as a mask and the injection for the impurity diffusion layer of the second conductivity type can be performed as a single step.

### Third Embodiment

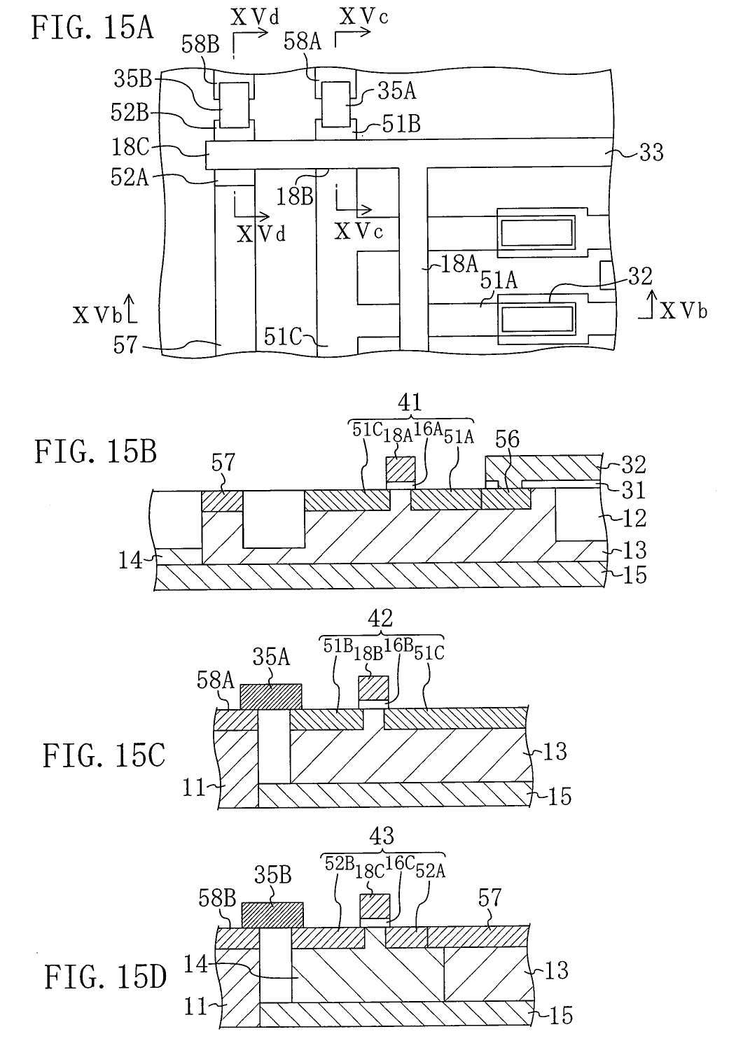

A third embodiment of the present invention will now be described with reference to the drawings. FIGS. 15A to 15D show an example of a semiconductor device according to the third embodiment of the present invention, wherein FIG. 15A is a plan view thereof, FIG. 15B is a cross-sectional view thereof taken along line XVb-XVb in FIG. 15A, FIG. 15C is a cross-sectional view thereof taken along line XVc-XVc in FIG. 15A, and FIG. 15D is a cross-sectional view thereof taken along line XVd-XVd in FIG. 15A.

The semiconductor device of the present embodiment includes a first protection transistor and a second protection transistor formed in the first well 13 of the first conductivity type, and a second protection transistor formed in the second well 14. Referring to FIGS. 15A to 15D, the semiconductor device of the present embodiment includes the semiconductor substrate 11 of the first conductivity type, and the deep well 15 of the second conductivity type. The first well 13 and the second well 14 are formed on the deep well 15.

The first protection transistor 41 and the second protection transistor 42 are formed in the first well 13. The first protection transistor 41 includes the first gate insulating film 16A and the first gate electrode 18A, which are formed in this order on the first well 13, and the first source/drain diffusion layer 51A of the second conductivity type and a common diffusion layer 51C of the second conductivity type, which are formed in the first well 13 on opposite sides of the first gate electrode 18A. The second protection transistor 42 includes the second gate insulating film 16B and the second gate electrode 18B, which are formed in this order on the first well 13, and the common diffusion layer 51C of the second conductivity type and the second source/drain diffusion layer 51B of the second conductivity type, which are formed in the first well 13 on opposite sides of the second gate electrode 18B. The first protection transistor 41 and the second protection transistor 42 share the common diffusion layer 51C.

The first source/drain diffusion layer 51A is in contact with the first diffusion layer 56 of the second conductivity type. The protected device electrode 32, being the gate electrode of the protected device, is formed on the first diffusion layer 56 with the insulating film 31 having an opening being interposed therebetween. The protected device electrode 32 is in contact with the first diffusion layer 56 through the opening.

The second diffusion layer 57 of the first conductivity type is formed in a region of the first well 13 delimited by the isolation insulating films 12.

A third gate electrode 18C is formed on the second well 14 with a third gate insulating film 16C being interposed therebetween. The third source/drain diffusion layer 52A of the first conductivity type and the fourth source/drain diffusion layer 52B of the first conductivity type are formed in the second well 14 on opposite sides of the third gate electrode 18C. The third source/drain diffusion layer 52A is in contact with the second diffusion layer 57.

The first connection diffusion layer 58A of the first conductivity type and a second connection diffusion layer 58B of the first conductivity type are formed each in a region of the semiconductor substrate 11 that is isolated by the isolation insulating film 12 from the region of the deep well 15. The first connection diffusion layer 58A and the second source/drain diffusion layer 51B are electrically connected with each other by the first conductive film 35A, being a connection electrode, and the second connection diffusion layer 58B and the fourth source/drain diffusion layer 52B are electrically connected with each other by the second conductive film 35B.

FIGS. 15A to 15D show an example where the first gate electrode 18A, the second gate electrode 18B and the third gate electrode 18C are connected with each other, thereby together forming a common electrode. Then, as compared with a case where the electrodes are independent of each other, the antenna ratio is improved. Therefore, when preventing the charge-up during the manufacturing process, a voltage of the same polarity as the voltage applied to the protected device electrode 32 is more reliably applied to the first gate electrode 18A, the second gate electrode 18B and the third gate electrode 18C. Thus, the protection effect can be obtained more stably. In FIGS. 15A to 15D, the first gate electrode 18A, the second gate electrode 18B and the third gate electrode 18C are also connected with the dummy electrode 33 extending in parallel to the protected device electrode 32, thereby together forming a common electrode. This further improves the antenna ratio.

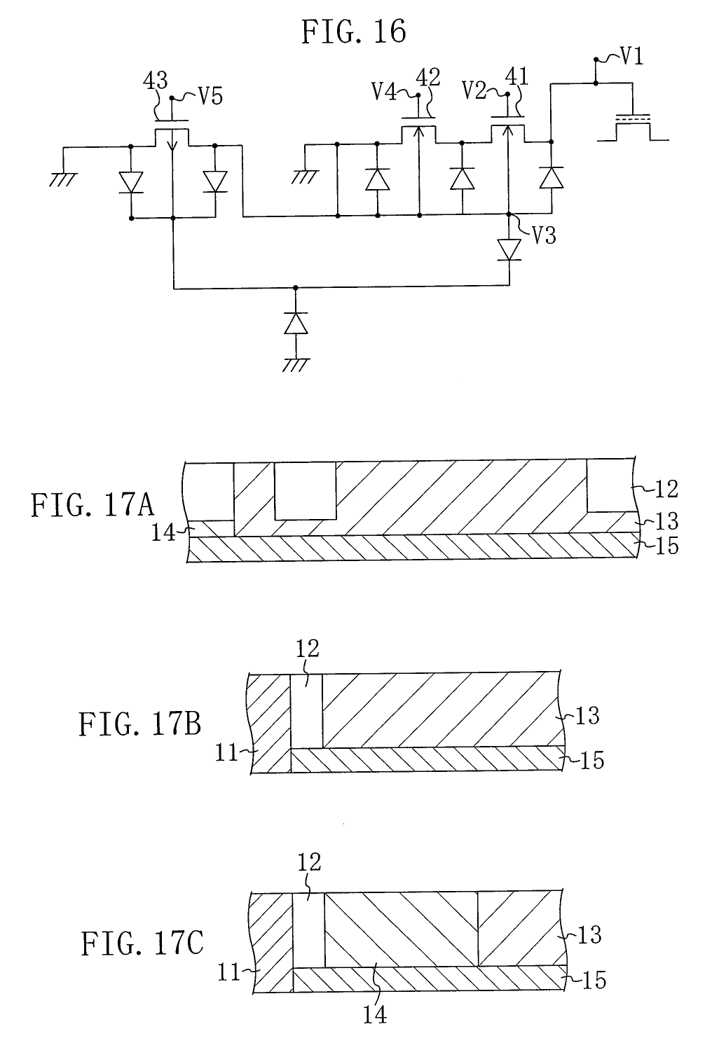

FIG. 16 shows an equivalent circuit of the semiconductor device shown in FIGS. 15A to 15D. Referring to FIG. 16, the first protection transistor 41, the second protection transistor 42 and a third protection transistor 43 are connected in series with the gate electrode of the memory device being the protected device. The first protection transistor 41 is formed by the first gate electrode 18A, the first source/drain diffusion layer 51A and the common diffusion layer 51C, as shown in FIGS. 15A to 15D. The second protection transistor 42 is formed by the second gate electrode 18B, the second source/drain diffusion layer 51B and the common diffusion layer 51C. The third protection transistor 43 is formed by the third gate electrode 18C, the third source/drain diffusion layer 52A and the fourth source/drain diffusion layer 52B. A PN junction diode is formed between each diffusion layer and a well, and between a well and the semiconductor substrate.

Next, a method for driving the semiconductor device of the present embodiment will be described with reference to FIGS. 15A to 15D and 16 and Table 3 below. It is assumed in the following description that the protected device electrode is the terminal V1, the first gate electrode is the terminal V2, the second well is the terminal V3, the second gate electrode is the terminal V4, and the third gate electrode is the terminal V5.

TABLE 3

| | V1 | V2 | V3 | V4 | V5 |
|---|---|---|---|---|---|
| Positive charge | positive | positive | open | positive | positive |
| during process | | | | | |
| Negative charge | negative | negative | open | negative | negative |
| during process | | | | | |
| Write | 9 | 0 | 0 | 0 | 0 |
| Erase | −6 | −6 | −6 | −6 | −6 |
| Read | 5 | 0 | 0 | 0 | 0 |

If a positive charge-up occurs during the manufacturing process, including before the wiring step, a positive voltage is applied to the terminal V1, the terminal V2, the terminal V4 and the terminal V5 as shown in Table 3, thus turning ON the first protection transistor 41 and the second protection transistor 42. Then, the charge passes through to the semiconductor substrate 11 via the protected device electrode 32, the first diffusion layer 56, the first source/drain diffusion layer 51A, the common diffusion layer 51C, the second source/drain diffusion layer 51B, the first conductive film 35A and the first connection diffusion layer 58A. Thus, it is possible to suppress the charge injection into the memory device or the charge drawing out of the memory device.

More specifically, the junction between the protected device electrode 32 and the first diffusion layer 56 is substantially a metal junction, and the potential difference therebetween is substantially 0 V. Since the first protection transistor 41 and the second protection transistor 42 are ON, the potential difference between the first source/drain diffusion layer 51A and the second source/drain diffusion layer 51B is substantially 0 V. Since the junction between the second source/drain diffusion layer 51B and the semiconductor substrate 11 is substantially a metal junction, the potential difference therebetween is substantially 0 V. Therefore, it is possible to suppress the overall positive charge-up during the manufacturing process to about 1 V.

If a negative charge-up occurs during the manufacturing process, including before the wiring step, a negative voltage is applied to the terminal V1, the terminal V2, the terminal V4 and the terminal V5, as shown in Table 3, thus turning ON the third protection transistor 43. Then, the charge passes through to the semiconductor substrate 11 via the protected device electrode 32, the first diffusion layer 56, the first well 13, the second diffusion layer 57, the third source/drain diffusion layer 52A, the second conductive film 35B and the second connection diffusion layer 58B. Thus, it is possible to suppress the charge injection into the memory device or the charge drawing out of the memory device.

More specifically, the junction between the protected device electrode 32 and the first diffusion layer 56 is substantially a metal junction, and the potential difference therebetween is substantially 0 V. The junction between the first diffusion layer 56 and the first well 13 is a forward-biased PN junction, and the potential difference therebetween is about 0.7 V. Since the second protection transistor 42 is ON, the potential difference between the third source/drain diffusion layer 52A and the fourth source/drain diffusion layer 52B is 0 V. Since the junction between the fourth source/drain diffusion layer 52B and the semiconductor substrate 11 is substantially a metal junction, the potential difference therebetween is substantially 0 V. Therefore, it is possible to suppress the overall negative charge-up during the manufacturing process to about 1 V.

Preferably, the antenna ratios of the terminal V1, the terminal V2, the terminal V4 and the terminal V5 are set to be about equal to one another or so that those of the terminal V2, the terminal V4 and the terminal V5 are greater than that of the terminal V1. Then, even when a small charge is applied to the protected device, the voltage applied to the first protection transistor 41, the second protection transistor 42 and the third protection transistor 43 exceeds the threshold voltage, thereby turning ON the first protection transistor 41, the second protection transistor 42 and the third protection transistor 43.

When injecting electrons into the memory device after the completion of the manufacturing process, 9 V, for example, can be applied to the terminal V1 and 0 V, for example, can be applied to each of the terminal V2 and the terminal V3, as shown in Table 3, to thereby apply an intended voltage to the memory device without activating the protection device. Thus, the operation of injecting electrons into the memory device is realized. Then, by applying a voltage at the same time to a bit line of the memory device and a well of the memory device, it is possible to realize various electron injecting operations such as the CHE current and the FN current.

When reading out a current from the memory device after the completion of the manufacturing process, 5 V can be applied to the terminal V1 and 0 V can be applied to each of the terminal V2 and the terminal V3, as shown in Table 3, to thereby apply an intended voltage to the memory device without activating the protection device. Thus, the operation of reading out a current from the memory device is realized. Then, by applying a voltage at the same time to a bit line of the memory device and a well of the memory device, it is possible to adjust the read characteristics.

When drawing electrons out of, or injecting positive holes into, the memory device after the completion of the manufacturing process, −6 V can be applied to each of the terminal V1, the terminal V2 and the terminal V3, as shown in Table 3, to thereby apply an intended voltage to the memory device without activating the protection device. Thus, the operation of drawing electrons out of, or injecting positive holes into, the memory device is realized. Then, by applying a voltage at the same time to a bit line of the memory device and a well of the memory device, it is possible to realize various electron drawing or positive hole injecting operations such as the BTBT current and the FN current.

An example of a method for manufacturing the semiconductor device of the third embodiment will now be described with reference to the drawings. FIGS. 17A to 21C show a sequence of steps in the method for manufacturing the semiconductor device of the third embodiment. FIGS. 17A, 18A, 19A, 20A and 21A show cross-sectional views taken along line XVb-XVb in FIG. 15A, FIGS. 17B, 18B, 19B, 20B and 21B show cross-sectional views taken along line XVc-XVc, and FIGS. 17C, 18C, 19C, 20C and 21C show cross-sectional views taken along line XVd-XVd.

First, referring to FIGS. 17A to 17C, the isolation insulating film 12, the first well 13 of the first conductivity type, the second well 14 of the second conductivity type and the deep well 15 of the second conductivity type are each formed in a predetermined region of the semiconductor substrate 11 of the first conductivity type, thus defining a memory device region, a first protection transistor region, a second protection transistor region and a third protection transistor region.

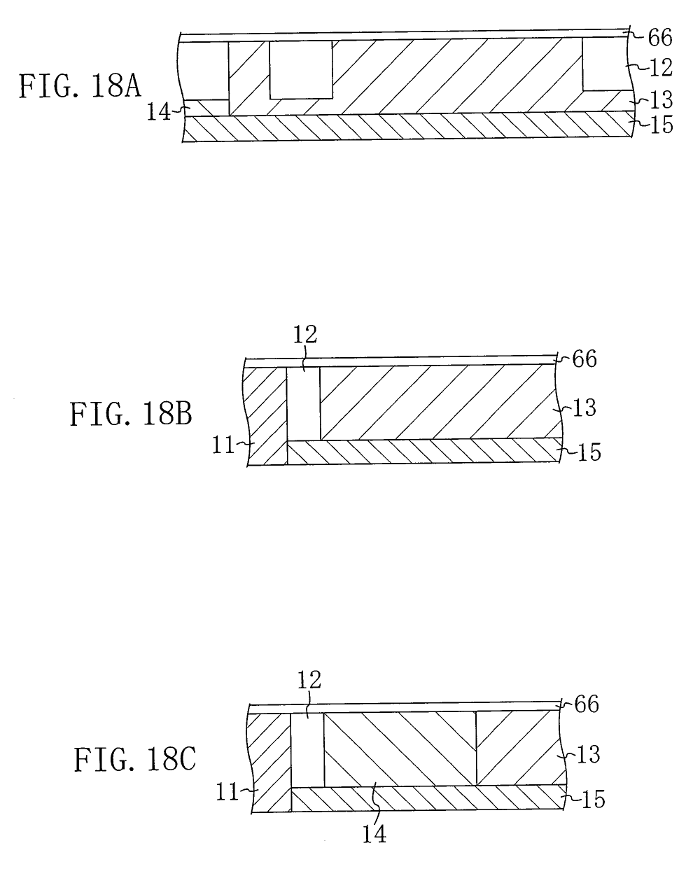

Then, referring to FIGS. 18A to 18C, the insulating film 66 having a thickness of 2 nm to 30 nm is formed across the memory device region, the first protection transistor region, the second protection transistor region and the third protection transistor region. The insulating film 66 may be a single piece of film provided across the memory device region, the first protection transistor region and the second protection transistor region, or may be a group of pieces of film provided independently for the regions.

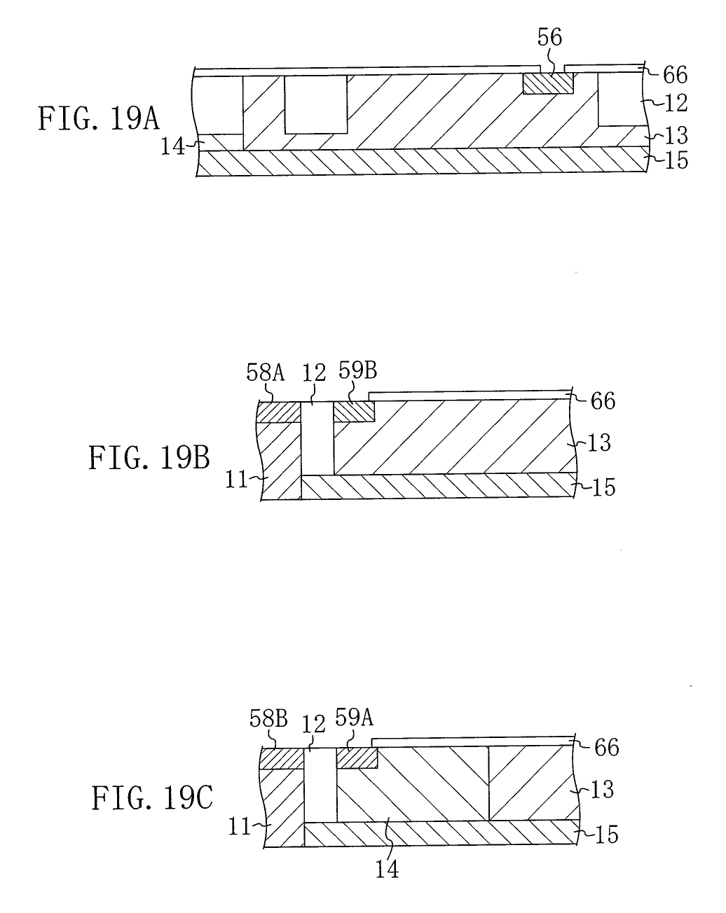

Then, referring to FIGS. 19A to 19C, an opening is formed in an area of the memory device region by removing a portion of the insulating film 66. Then, an impurity of the second conductivity type is injected at a dose of 1×10¹⁵/cm², for example, into the first well 13 through the opening, thereby forming the first diffusion layer 56. Instead of using such a method, the impurity of the second conductivity type may be injected via the insulating film 66 during an injection process for setting the threshold (Vt) of peripheral transistors, for example.

Then, the insulating film 66 is removed selectively, and an impurity of the first conductivity type is injected at a dose of 1×10¹⁵/cm², for example, thereby forming the first connection diffusion layer 58A in a region of the semiconductor substrate 11 that is outside the region of the deep well 15 and that is adjacent to the first well 13, and forming the second connection diffusion layer 58B in a region that is adjacent to the second well 14. The first conductivity type diffusion layer 59A is formed in a region of the second well 14 that is opposing the second connection diffusion layer 58B with the isolation insulating film 12 being interposed therebetween. The first conductivity type diffusion layer 59A is later to be integral with the fourth source/drain diffusion layer 52B. An impurity of the second conductivity type is injected at a dose of 1×10¹⁵/cm², for example, thereby forming the second conductivity type diffusion layer 59B in a region of the first well 13 that is opposing the first connection diffusion layer 58A with the isolation insulating film 12 being interposed therebetween. The second conductivity type diffusion layer 59B is later to be integral with the second source/drain diffusion layer 51B.

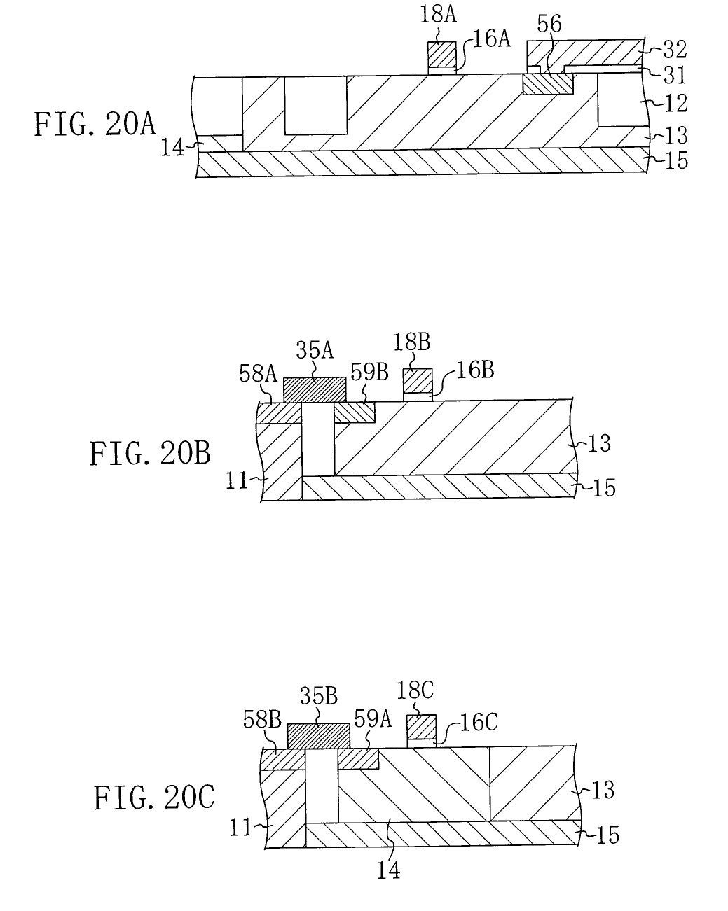

Then, Referring to FIGS. 20A to 20C, the protected device electrode 32 being the gate electrode of the memory device is formed in the memory device formation region, the first gate electrode 18A in the first protection transistor formation region, the second gate electrode 18B in the second protection transistor region, and the third gate electrode 18C in the third protection transistor region. Moreover, the first conductive film 35A and the second conductive film 35B are formed. The first conductive film 35A extends over the isolation insulating film 12 to electrically connect the second conductivity type diffusion layer 59B and the first connection diffusion layer 58A with each other, and the second conductive film 35B extends over the isolation insulating film 12 to electrically connect the first conductivity type diffusion layer 59A and the second connection diffusion layer 58B with each other. Through the heat treatment in this step, the extent of distribution of the first diffusion layer 56 grows larger than immediately after the injection. The protected device electrode 32 may be formed so as to be in direct contact with the first diffusion layer 56 through the opening. Alternatively, there may exist an insulating film having a thickness of 4 nm or less at the interface therebetween. If the thickness of such an insulating film is 4 nm or less, the protected device electrode 32 and the first diffusion layer 56 are bonded together substantially in metallic bonding, and it is possible to ensure a sufficient electric connection between the protected device electrode 32 and the first diffusion layer 56. The presence of an insulating film having a thickness of 4 nm or less reduces the possibility of abnormal Si growth from the substrate, thereby increasing the process stability.

The protected device electrode 32 may have a two-layer structure including an upper layer and a lower layer. In such a case, the lower layer of the electrode is first deposited, and then a region at least including the opening is etched away. Then, an impurity of the first conductivity type is injected through the opening to form the first diffusion layer, and then an upper layer of the electrode is further deposited thereon. Thus, through the opening, the upper layer of the electrode and the first diffusion layer are connected with each other directly or indirectly with an insulating film having a thickness of 4 nm or less being interposed therebetween.

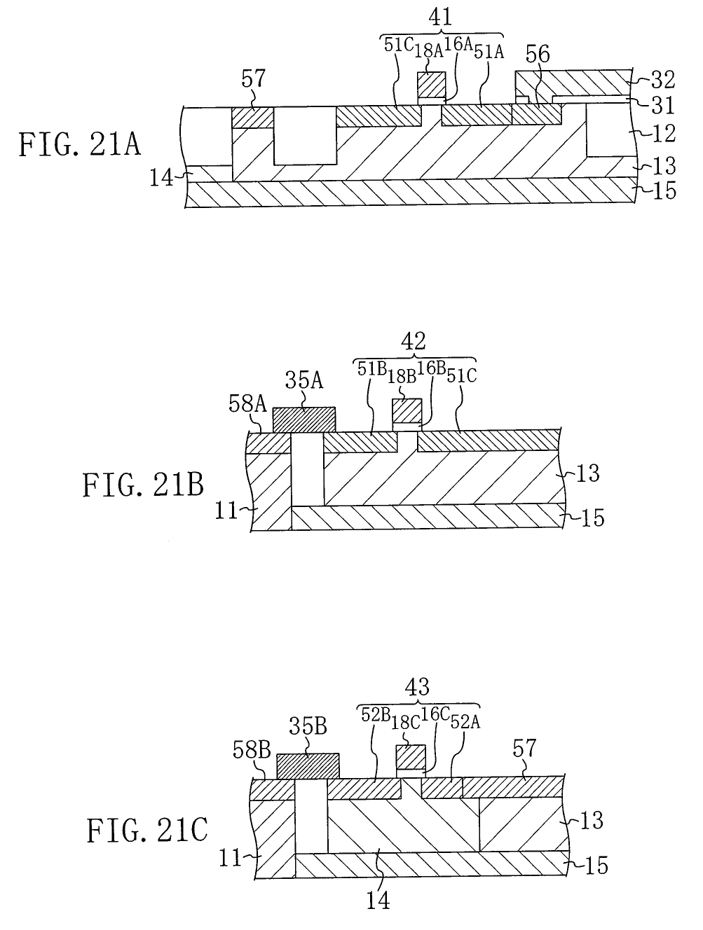

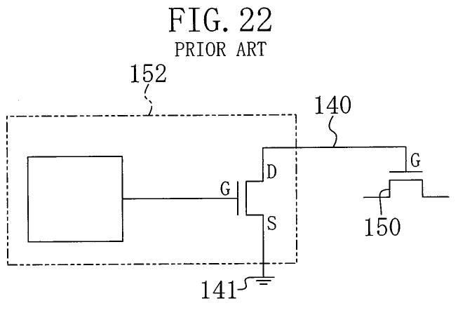

Then, referring to FIGS. 21A to 21C, an impurity of the second conductivity type is injected at a dose of 1×10¹⁵/cm², for example, into regions of the first well 13 on opposite sides of the first gate electrode 18A. Thus, the first source/drain diffusion layer 51A, the second source/drain diffusion layer 51B, and the common diffusion layer 51C are formed. In this process, the ion implantation is performed so that the first source/drain diffusion layer 51A and the first diffusion layer 56 are in contact with each other. Moreover, the ion implantation is performed so that the second source/drain diffusion layer 51B and the second conductivity type diffusion layer 59B are in contact with, and integral with, each other. Thus, the second source/drain diffusion layer 51B is connected with the semiconductor substrate 11 via the first conductive film 35A and the first connection diffusion layer 58A.

Moreover, an impurity of the first conductivity type is injected at a dose of 1×10¹⁵/cm², for example, into regions of the second well 14 on opposite sides of the second gate electrode 18B. Thus, the third source/drain diffusion layer 52A and the fourth source/drain diffusion layer 52B are formed on opposite sides of the second gate electrode 18B. This process is performed so that the fourth source/drain diffusion layer 52B and the first conductivity type diffusion layer 59A are in contact with, and integral with, each other. Thus, the fourth source/drain diffusion layer 52B is connected with the semiconductor substrate 11 via the second conductive film 35B and the second connection diffusion layer 58B.

Moreover, an impurity of the first conductivity type is injected into the first well 13 so as to form the second diffusion layer 57 isolated from the second source/drain diffusion layer 51B. In this process, the second diffusion layer 57 is formed on the first well 13 and the second well 14 so as to be in contact with the third source/drain diffusion layer 52A over the second well 14. The order in which the impurity injection processes are performed is not limited to any particular order. Impurity injection processes of the same conductivity type may be combined together.

Instead of using the isolation insulating film 12 for the isolation between the second source/drain diffusion layer 51B and the semiconductor substrate 11, the isolation may be provided by a diffusion layer of the first conductivity type. In such a case, instead of using the first conductive film 35A on the isolation insulating film 12 for the connection between the second source/drain diffusion layer 51B and the semiconductor substrate 11, the connection may be made by a metal silicide shunt structure formed on the semiconductor substrate 11. In such a case, the first connection diffusion layer 58A and the second conductivity type diffusion layer 59B do not need to be formed in the manufacturing process as described above, and the dose may be about 1×10¹⁴/cm².

The isolation between the fourth source/drain diffusion layer 52B and the semiconductor substrate 11 may be provided also by a diffusion layer, wherein the connection therebetween is made by a metal silicide shunt structure formed on the semiconductor substrate 11.

For each of the protected device, the first protection transistor, the second protection transistor and the third protection transistor, a sidewall may be formed beside the gate electrode, or an extension region, or the like, may be provided in the diffusion layer.

A metal silicide layer may be formed over the first source/drain diffusion layer 51A, the second source/drain diffusion layer 51B, the common diffusion layer 51C, the third source/drain diffusion layer 52A, the fourth source/drain diffusion layer 52B and the second diffusion layer 57. This increases the drive capability of each protection transistor, thereby improving the effect of shunting the current in case of a charge-up during the manufacturing process.

As described above, with the semiconductor device of the present embodiment, the effect of protecting the protected device can be exerted as early as from the FEOL process, whereas the effect was exerted only at and after the wiring step with the conventional technique.

Moreover, while a negative voltage cannot be applied to the protected device after the completion of the manufacturing process with the structure of the conventional technique, the semiconductor device of the present embodiment allows for the application of a high voltage of the positive or negative polarity to the protected device after the completion of the manufacturing process.

In the present embodiment, the gate electrode of the memory device being the protected device is connected with the source/drain diffusion layer of the first protection transistor via the first diffusion layer, thereby exerting the protection effect as early as from the FEOL process. However, it is also effective to employ a structure where the gate electrode of the memory device and the source/drain diffusion layer of the first protection transistor are connected with each other through a wiring step similar to that of the conventional technique. Although the protected device is then protected at and after the wiring step, it is possible to apply a high voltage of the negative polarity to the memory device for driving the memory device after the completion of the manufacturing process, and it is possible to reduce the number of steps in the manufacturing process and to decrease the level of difficulty of the manufacturing process because diffusion layers in the substrate are not directly connected with each other.

With the semiconductor device of the third embodiment, a larger layout area is required for the formation of the protection structure, as compared with the first embodiment, but the impurity diffusion layer of the second conductivity type can be formed easily. Specifically, where the memory device being the protected device is a non-volatile memory using a two-layer electrode including an upper layer and a lower layer, the injection for the source/drain section of the memory device using the lower layer as a mask and the injection for the impurity diffusion layer of the second conductivity type can be performed as a single step.

Although the semiconductor device of the present embodiment requires three protection transistors, the connection between the second source/drain diffusion layer and the semiconductor substrate and the connection between the fourth source/drain diffusion layer and the semiconductor substrate can be formed on the same side (the dummy electrode side). Thus, the layout area can be reduced.

While the first and second conductivity types are the n type and the p type, respectively, in the embodiments above, effects as described above can be obtained also with the opposite polarity setting.

As described above, the present invention realizes a semiconductor device, in which a memory device is protected across positive and negative low-voltage ranges from the charge-up during the diffusion step in the FEOL process, and in which a high voltage of the positive or negative polarity necessary for driving the memory device can be applied to the memory device after the completion of the manufacturing process. Particularly, the present invention is useful as a semiconductor device such as a local charge trapping type non-volatile memory, a method for manufacturing the same, and a method for driving the same.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device, comprising:
a semiconductor substrate of a first conductivity type, including a first well of the first conductivity type and a second well of a second conductivity type;
a protected device formed on the semiconductor substrate and including a protected device electrode;
a first protection transistor formed in the second well;
a second protection transistor formed in the first well;
a first diffusion layer of the first conductivity type formed in the second well and being in contact with the protected device electrode; and
a second diffusion layer of the first conductivity type formed in the first well, wherein:
the first protection transistor includes a first gate electrode formed on the second well, and a first source/drain diffusion layer of the first conductivity type and a second source/drain diffusion layer of the first conductivity type formed in the second well on opposite sides of the first gate electrode;
the second protection transistor includes a second gate electrode formed on the first well, and a third source/drain diffusion layer of the second conductivity type and a fourth source/drain diffusion layer of the second conductivity type formed in the first well on opposite sides of the second gate electrode;
the fourth source/drain diffusion layer is in contact with the second diffusion layer;
the third source/drain diffusion layer extends into the second well beyond the boundary between the first well and the second well, and is in contact with the second source/drain diffusion layer; and
the first source/drain diffusion layer is in contact with the first diffusion layer.

2. The semiconductor device of claim 1, wherein a surface of each of the first source/drain diffusion layer, the second source/drain diffusion layer, the third source/drain diffusion layer, the fourth source/drain diffusion layer and the second diffusion layer is made into a metal silicide.

3. The semiconductor device of claim 1, wherein the first gate electrode and the second gate electrode are connected with each other.

4. The semiconductor device of claim 1, further comprising a dummy electrode extending in parallel to the protected device electrode,
wherein the first gate electrode and the second gate electrode are each connected with the dummy electrode.

5. The semiconductor device of claim 1, wherein:
the protected device electrode has a layered structure including an upper layer and a lower layer; and
the first diffusion layer is in contact with the upper layer.

6. The semiconductor device of claim 1, wherein the protected device electrode and the first diffusion layer are in contact with each other via an insulating film having a thickness of 4 nm or less being interposed therebetween.

7. The semiconductor device of claim 1, wherein the protected device is a non-volatile memory a characteristic of which changes by accumulating/removing electrons/positive holes into/from a charge accumulation layer.

8. A semiconductor device, comprising:
a semiconductor substrate of a first conductivity type, including a selectively-formed deep well of a second conductivity type, a first well of the first conductivity type and a second well of the second conductivity type formed on the deep well;
a protected device formed on the semiconductor substrate and including a protected device electrode;
a first protection transistor formed in the first well;
a first protection transistor formed in the second well;
a first diffusion layer of the first conductivity type formed in the first well and being in contact with the protected device electrode; and
a second diffusion layer of the first conductivity type spaced apart from the first protection transistor, wherein:
the first protection transistor includes a first gate electrode formed on the first well, and a first source/drain diffusion layer of the second conductivity type and a second source/drain diffusion layer of the second conductivity type formed in the first well on opposite sides of the first gate electrode;
the second protection transistor includes a second gate electrode formed on the second well, and a third source/drain diffusion layer of the first conductivity type and a fourth source/drain diffusion layer of the first conductivity type formed in the second well on opposite sides of the second gate electrode;
the first source/drain diffusion layer is in contact with the first diffusion layer;
the second source/drain diffusion layer is electrically connected with a region of the semiconductor substrate excluding a region where the deep well is formed with a first conductive film formed on the semiconductor substrate being interposed therebetween;
the third source/drain diffusion layer is in contact with the second diffusion layer; and
the fourth source/drain diffusion layer is electrically connected with a region of the semiconductor substrate excluding a region where the deep well is formed with a second conductive film formed on the semiconductor substrate being interposed therebetween.

9. The semiconductor device of claim 8, wherein a gate electrode of the protected device is formed by the same material as the first conductive film and the second conductive film.

10. The semiconductor device of claim 8, further comprising a first connection diffusion layer of the first conductivity type and a second connection diffusion layer of the first conductivity type formed in a region of the semiconductor substrate excluding a region where the deep well is formed, wherein:
the first conductive film is in contact with the second source/drain diffusion layer and the first connection diffusion layer; and
the second conductive film is in contact with the fourth source/drain diffusion layer and the second connection diffusion layer.

11. The semiconductor device of claim 8, wherein a surface of each of the first source/drain diffusion layer, the second source/drain diffusion layer, the third source/drain diffusion layer, the fourth source/drain diffusion layer and the second diffusion layer is made into a metal silicide.

12. The semiconductor device of claim 8, wherein the first gate electrode and the second gate electrode are electrically connected with each other.

13. The semiconductor device of claim 8, further comprising a dummy electrode extending in parallel to the protected device electrode,
wherein the first gate electrode and the second gate electrode are each connected with the dummy electrode.

14. The semiconductor device of claim 8, wherein:
the protected device electrode has a layered structure including an upper layer and a lower layer; and
the first diffusion layer is in contact with the upper layer.

15. The semiconductor device of claim 8, wherein the protected device electrode and the first diffusion layer are in contact with each other with an insulating film having a thickness of 4 nm or less being interposed therebetween.

16. The semiconductor device of claim 8, wherein the protected device is a non-volatile memory a characteristic of which changes by accumulating/removing electrons/positive holes into/from a charge accumulation layer.

17. A semiconductor device, comprising:
a semiconductor substrate of a first conductivity type, including a selectively-formed deep well of a second conductivity type, a first well of the first conductivity type and a second well of the second conductivity type formed on the deep well;
a protected device formed on the semiconductor substrate and including a protected device electrode;
a first protection transistor and a second protection transistor formed in the first well;
a third protection transistor formed in the second well;
a first diffusion layer of the first conductivity type formed in the first well and being in contact with the protected device electrode; and
a second diffusion layer of the first conductivity type formed in the first well spaced apart from the first protection transistor and the second protection transistor, wherein:
the first protection transistor includes a first gate electrode formed on the first well, a first source/drain diffusion layer of the second conductivity type and a common diffusion layer of the second conductivity type formed in the first well on opposite sides of the first gate electrode;
the second protection transistor includes a second gate electrode formed on the first well, a second source/drain diffusion layer of the second conductivity type and the common diffusion layer of the second conductivity type formed in the first well on opposite sides of the second gate electrode;
the third protection transistor includes a third gate electrode formed on the second well, and a third source/drain diffusion layer of the first conductivity type and a fourth source/drain diffusion layer of the first conductivity type formed in the second well on opposite sides of the third gate electrode;
the first source/drain diffusion layer is in contact with the first diffusion layer;
the second source/drain diffusion layer is electrically connected with a region of the semiconductor substrate excluding a region where the deep well is formed with a first conductive film formed on the semiconductor substrate being interposed therebetween;
the third source/drain diffusion layer is in contact with the second diffusion layer; and
the fourth source/drain diffusion layer is electrically connected with a region of the semiconductor substrate excluding a region where the deep well is formed with a second conductive film formed on the semiconductor substrate being interposed therebetween.

18. The semiconductor device of claim 17, wherein the protected device electrode is formed by the same material as the first conductive film and the second conductive film.

19. The semiconductor device of claim 17, further comprising a first connection diffusion layer of the first conductivity type and a second connection diffusion layer of the first conductivity type formed in a region of the semiconductor substrate excluding a region where the deep well is formed, wherein:
the first conductive film is in contact with the second source/drain diffusion layer and the first connection diffusion layer; and
the second conductive film is in contact with the fourth source/drain diffusion layer and the second connection diffusion layer.

20. The semiconductor device of claim 17, wherein a surface of each of the first source/drain diffusion layer, the common diffusion layer, the second source/drain diffusion layer, the third source/drain diffusion layer, the fourth source/drain diffusion layer and the second diffusion layer is made into a metal silicide.

21. The semiconductor device of claim 17, wherein the first gate electrode, the second gate electrode and the third gate electrode are electrically connected with one another.

22. The semiconductor device of claim 17, further comprising a dummy electrode extending in parallel to the protected device electrode,
wherein the first gate electrode, the second gate electrode and the third gate electrode are each connected with the dummy electrode.

23. The semiconductor device of claim 17, wherein:
the protected device electrode has a layered structure including an upper layer and a lower layer; and
the first diffusion layer is connected with the upper layer.

24. The semiconductor device of claim 17, wherein the protected device electrode and the first diffusion layer are in contact with each other with an insulating film having a thickness of 4 nm or less being interposed therebetween.

25. The semiconductor device of claim 17, wherein the protected device is a non-volatile memory a characteristic of which changes by accumulating/removing electrons/positive holes into/from a charge accumulation layer.

26. A method for manufacturing a semiconductor device, comprising:
a step (a) of forming a first well of a first conductivity type and a second well of a second conductivity type in a semiconductor substrate of the first conductivity type;
a step (b) of forming an insulating film on the first well and on the second well;
a step (c) of forming an opening in a portion of the insulating film on the second well;
a step (d) of introducing an impurity into the second well through the opening to thereby form a first diffusion layer of the first conductivity type in the second well;
a step (e) of forming a conductive film on the insulating film and the opening and then patterning the formed conductive film, thereby forming a first gate electrode on the second well, a second gate electrode on the first well, and a gate electrode of a protected device in contact with the first diffusion layer;
a step (f) of forming a first source/drain diffusion layer of the first conductivity type and a second source/drain diffusion layer of the first conductivity type in the second well on opposite sides of the first gate electrode;
a step (g) of forming a second diffusion layer of the first conductivity type in the first well; and
a step (h) of forming a third source/drain diffusion layer of the second conductivity type and a fourth source/drain diffusion layer of the second conductivity type in the first well on opposite sides of the second gate electrode, wherein:
the step (f) is performed so that the first source/drain diffusion layer and the first diffusion layer are connected with each other;
the step (h) is performed so that the third source/drain diffusion layer extends into the second well so as to be in contact with the second source/drain diffusion layer; and
the step (g) is performed so that the fourth source/drain diffusion layer and the second diffusion layer are in contact with each other.

27. A method for manufacturing a semiconductor device, comprising:
a step (a) of forming a first well of a first conductivity type and a second well of a second conductivity type in a semiconductor substrate of the first conductivity type, and forming a deep well of the second conductivity type under the first well and the second well so as to be in contact with a bottom surface of the first well and the second well;
a step (b) of forming an insulating film on the first well and on the second well;
a step (c) of forming an opening in a portion of the insulating film on the first well;
a step (d) of introducing an impurity into the first well through the opening to thereby form a first diffusion layer of the second conductivity type in the first well;
a step (e) of forming a conductive film on the insulating film and the opening and then patterning the formed conductive film, thereby forming a first gate electrode on the first well, a second gate electrode on the second well, and a protected device electrode in contact with the first diffusion layer;
a step (f) of forming a first source/drain diffusion layer of the second conductivity type and a second source/drain diffusion layer of the second conductivity type in the first well on opposite sides of the first gate electrode;
a step (g) of forming a third source/drain diffusion layer of the first conductivity type and a fourth source/drain diffusion layer of the first conductivity type in the second well on opposite sides of the second gate electrode, and forming a second diffusion layer of the first conductivity type in the first well so as to be in contact with the third source/drain diffusion layer;
a step (h) of forming a first connection diffusion layer of the first conductivity type in the semiconductor substrate beside the first well, and forming a second connection diffusion layer of the first conductivity type beside the second well; and
a step (i) of electrically connecting the second source/drain diffusion layer and the first connection diffusion layer with each other, and electrically connecting the fourth source/drain diffusion layer and the second connection diffusion layer with each other, wherein:
the step (f) is performed so that the first source/drain diffusion layer and the first diffusion layer are in contact with each other; and
the step (g) is performed so that the second diffusion layer is spaced apart from the first source/drain diffusion layer and the second source/drain diffusion layer.

28. The semiconductor device of claim 27, wherein the step (h) is performed before the step (g).

29. A method for manufacturing a semiconductor device, comprising:
a step (a) of forming a first well of a first conductivity type and a second well of a second conductivity type in a semiconductor substrate of the first conductivity type, and forming a deep well of the second conductivity type under the first well and the second well so as to be in contact with a bottom surface of the first well and the second well;
a step (b) of forming an insulating film on the first well and on the second well;
a step (c) of forming an opening in a portion of the insulating film on the first well;
a step (d) of introducing an impurity into the first well through the opening to thereby form a first diffusion layer of the second conductivity type in the first well;
a step (e) of forming a conductive film on the insulating film and the opening and then patterning the formed conductive film, thereby forming a first gate electrode and a second gate electrode on the first well, a third gate electrode on the second well, and a protected device electrode in contact with the first diffusion layer;
a step (f) of forming a common diffusion layer of the second conductivity type in the first well between the first gate electrode and the second gate electrode, forming a first source/drain diffusion layer of the second conductivity type beside the first gate electrode, and forming a second source/drain diffusion layer of the second conductivity type beside the second gate electrode;
a step (g) of forming a third source/drain diffusion layer of the first conductivity type and a fourth source/drain diffusion layer of the first conductivity type in the second well on opposite sides of the third gate electrode, and forming a second diffusion layer of the first conductivity type in the first well so as to be in contact with the third source/drain diffusion layer;
a step (h) of forming a first connection diffusion layer of the first conductivity type in the semiconductor substrate beside the first well, and forming a second connection diffusion layer of the first conductivity type beside the second well; and
a step (i) of electrically connecting the second source/drain diffusion layer and the first connection diffusion layer with each other, and electrically connecting the fourth source/drain diffusion layer and the second connection diffusion layer with each other, wherein:
the step (f) is performed so that the first source/drain diffusion layer and the first diffusion layer are in contact with each other; and
the step (g) is performed so that the second diffusion layer is spaced apart from the first source/drain diffusion layer and the second source/drain diffusion layer.

30. The semiconductor device of claim 29, wherein the step (h) is performed before the step (g).

31. A method for driving the semiconductor device of claim 1, comprising the steps of:
applying an equal positive potential to the protected device electrode, the first gate electrode and the second well for performing an operation of injecting electrons into the protected device and an operation of reading out from the protected device; and
applying a negative potential to the protected device electrode and a ground potential to the first gate electrode and the second well for performing an operation of injecting positive holes into the protected device and an operation of drawing electrons out of the protected device.

32. A method for driving the semiconductor device of claim 8, comprising the steps of:
applying a positive potential to the protected device electrode and a ground potential to the first gate electrode and the first well for performing an operation of injecting electrons into the protected device and an operation of reading out from the protected device; and
applying a negative potential to the protected device electrode, the first gate electrode and the second well for performing an operation of injecting positive holes into the protected device and an operation of drawing electrons out of the protected device.

33. A method for driving the semiconductor device of claim 17, comprising the steps of:
applying a positive potential to the protected device electrode and a ground potential to the first gate electrode and the first well for performing an operation of injecting electrons into the protected device and an operation of reading out from the protected device; and
applying a negative potential to the protected device electrode, the first gate electrode and the second well for performing an operation of injecting positive holes into the protected device and an operation of drawing electrons out of the protected device.
